(19) United States
(12) Patent Application Publication
(10) Pub. No.: US 2026/0269835 A1
(43) Pub. Date: Sep. 10, 2026

(54) TRANSMITTER FOR OPERATION WITH RESTRICTED POWER CONSUMPTION

(71) Applicant: Telefonaktiebolaget LM Ericsson (publ), Stockholm (SE)

(72) Inventors: Henrik SJÖLAND, LUND (SE); Rickard LJUNG, HELSINGBORG (SE); Bipin BALAKRISHNAN, MALMÖ (SE); Fredrik DAHLGREN, LUND (SE); Gang ZOU, LUND (SE); Shousheng HE, SÖDRA SANDBY (SE)

(21) Appl. No.: 18/881,369

(22) PCT Filed: Jul. 7, 2022
(86) PCT No.: PCT/EP2022/068943

§ 371 Date: Jan. 6, 2025

(51) Int. Cl. H03L 7/14; H04B 1/04; H04L 27/12

(52) U.S. Cl. CPC H03L 7/146; H04B 1/04; H04L 27/127; H04B 2001/0491

(57) ABSTRACT

A transmitter is disclosed for operation with restricted power consumption. The transmitter comprises a signal generation oscillator configured to provide a signal for transmission, a phase-locked loop (PLL) configured to calibrate an oscillator frequency of the signal generation oscillator in relation to a reference frequency by providing a first control signal to the signal generation oscillator, and holding circuitry configured to maintain a digital representation of the first control signal provided by the PLL for provision of a second control signal to the signal generation oscillator when the PLL is inactive. A circuit chip comprising the transmitter is also disclosed. The circuit chip may further comprise a wake-up receiver (WUR). A communication device comprising the transmitter and/or the circuit chip is also disclosed. The communication device may further comprise a default transceiver configured for operation with power consumption which is higher than the restricted power consumption of the transmitter. For example, the transmitter may be configured to be operative while the default transceiver is in sleep mode.

### TECHNICAL FIELD

The present disclosure relates generally to the field of wireless transmitters. More particularly, it relates to transmitters operating with restricted power consumption.

### BACKGROUND

Power consumption is a typical concern in relation to communication devices. This may be particularly relevant when the power source of a communication device is limited.

Therefore, there is a need for transmitters operating with restricted (e.g., relatively low) power consumption.

### SUMMARY

It should be emphasized that the term “comprises/comprising” (replaceable by “includes/including”) when used in this specification is taken to specify the presence of stated features, integers, steps, or components, but does not preclude the presence or addition of one or more other features, integers, steps, components, or groups thereof. As used herein, the singular forms “a”, “an” and “the” are intended to include the plural forms as well, unless the context clearly indicates otherwise.

Generally, when an arrangement is referred to herein, it is to be understood as a physical product; e.g., an apparatus. The physical product may comprise one or more parts, such as controlling circuitry in the form of one or more controllers, one or more processors, or the like.

A first aspect is a transmitter for operation with restricted power consumption. The transmitter comprises a signal generation oscillator configured to provide a signal for transmission, a phase-locked loop (PLL) configured to calibrate an oscillator frequency of the signal generation oscillator in relation to a reference frequency, by providing a first control signal to the signal generation oscillator, and holding circuitry configured to maintain a digital representation of the first control signal provided by the PLL, for provision of a second control signal to the signal generation oscillator when the PLL is inactive.

In some embodiments, the PLL has a feedback path from the signal generation oscillator.

In some embodiments, the feedback path comprises a frequency divider configured to specify a ratio between the reference frequency and the oscillator frequency.

In some embodiments, the PLL comprises an error detector configured to receive the reference frequency and a feedback signal provided by the feedback path, and to provide a corresponding phase difference indicator, and a loop filter configured to provide the first control signal based on the phase difference indicator.

In some embodiments, the PLL is an analog PLL and further comprises one or more controlled current sources configured to provide charging based on the phase difference indicator, and the loop filter is configured to provide the first control signal responsive to the charging.

In some embodiments, the transmitter further comprises a reference oscillator configured to provide the reference frequency.

In some embodiments, the holding circuitry comprises a successive approximation register (SAR).

In some embodiments, the transmitter further comprises a digital-to-analog converter (DAC) configured to provide the second control signal to the signal generation oscillator based on the digital representation of the first control signal maintained by the holding circuitry.

In some embodiments, the transmitter further comprises comparing circuitry configured to provide an input to the holding circuitry based on a difference between the first control signal and the second control signal.

In some embodiments, the transmitter further comprises switching circuitry configured to provide the first control signal to the signal generation oscillator when the PLL is active, and to provide the second control signal to the signal generation oscillator when the PLL is inactive.

In some embodiments, the transmitter further comprises controlling circuitry configured to cause the PLL to be active during a calibration phase, wherein the first control signal is provided to the signal generation oscillator during the calibration phase. The controlling circuitry is also configured to cause the holding circuitry and the PLL to be active during a settling phase, wherein the settling phase follows the calibration phase, wherein the first control signal is provided to the signal generation oscillator during the settling phase, and wherein the digital representation of the first control signal is attained by the holding circuitry during the settling phase. The controlling circuitry is also configured to cause the holding circuitry to be active and the PLL to be inactive during a maintenance phase, wherein the maintenance phase follows the settling phase, and wherein the second control signal is provided to the signal generation oscillator during the maintenance phase.

In some embodiments, the signal generation oscillator is operatively connectable to an antenna via tapping circuitry.

In some embodiments, the transmitter is configured to modulate the signal for transmission using on-off keying (OOK).

In some embodiments, the transmitter is configured to operate the signal generation oscillator in an active mode for provision of an on-symbol of the OOK and in an inactive mode for provision of an off-symbol of the OOK.

In some embodiments, the transmitter is configured to operate the tapping circuitry between a signal transfer mode for provision of an on-symbol of the OOK and a signal blocking mode for provision of an off-symbol of the OOK.

In some embodiments, the second control signal is an approximation of the first control signal.

In some embodiments, the transmitter is configured to modulate the signal for transmission using frequency shift keying (FSK).

In some embodiments, the transmitter is configured to dynamically adjust—for each FSK symbol—the digital representation of the first control signal provided by the holding circuitry to provide the second control signal as having a value that corresponds to the frequency for the FSK symbol.

In some embodiments, the signal generation oscillator comprises a varactor configured to provide a shift of the frequency provided by the signal generation oscillator, and the transmitter is configured to dynamically adjust—for each FSK symbol—a bias voltage of the varactor to provide the shift of the frequency provided by the signal generation oscillator as corresponding to the frequency shift for the FSK symbol.

In some embodiments, a default transceiver is comprised in a same communication device as the transmitter. The default transceiver is configured for operation with power consumption which is higher than the restricted power consumption of the transmitter and configured to be inactive while the communication device is in sleep mode, and the signal for transmission comprises a signal to be transmitted when the communication device is in sleep mode.

In some embodiments, the signal to be transmitted when the communication device is in the sleep mode comprises one or more of: a radio link monitoring (RLM) report, a deep sleep monitoring (DSM) response, a response to, or confirmation of, a message received by a wake-up receiver (WUR) comprised in the same communication device as the transmitter, a device status report, a configuration report, and a do-not-disturb indication.

In some embodiments, the signal for transmission comprises an amount of data which is smaller than a data amount threshold.

A second aspect is an integrated circuit comprising the transmitter of the first aspect.

In some embodiments, the integrated circuit further comprises a wake-up receiver (WUR).

A third aspect is an integrated circuit chip comprising the integrated circuit of the second aspect.

A fourth aspect is a communication device comprising one or more of: the transmitter of the first aspect, the integrated circuit of the second aspect, and the integrated circuit chip of the third aspect.

In some embodiments, the communication device further comprises a default transceiver configured for operation with power consumption which is higher than the restricted power consumption of the transmitter.

In some embodiments, the transmitter is configured to be operative while the communication device is in sleep mode.

In some embodiments, the communication device is powered only by a non-changeable, or non-rechargeable, power source and/or unpredictable power supply.

In some embodiments, any of the above aspects may additionally have features identical with or corresponding to any of the various features as explained above for any of the other aspects.

An advantage of some embodiments is that transmitters operating with restricted (e.g., relatively low) power consumption are provided. For example, a transmitter disclosed herein may be able to transmit a signal with lower power consumption than other transmitters (e.g., other transmitters of a similar signal).

An advantage of some embodiments is that transmitters are provided which can be implemented with relatively small circuit area.

An advantage of some embodiments is that transmitters are provided which are suitable for operation during sleep mode of a communication device in which the transmitter is comprised.

An advantage of some embodiments is that radio link monitoring is enabled for a communication device in sleep mode.

An advantage of some embodiments is that some data may be transmitted from a communication device in sleep mode.

An advantage of some embodiments is that signal transmission by a low power transmitter may be performed with relatively low frequency error (e.g., compared to other transmitters with similar power consumption). This entails that the signal may be received with relatively high accuracy.

### BRIEF DESCRIPTION OF THE DRAWINGS

Further objects, features and advantages will appear from the following detailed description of embodiments, with reference being made to the accompanying drawings. The drawings are not necessarily to scale, emphasis instead being placed upon illustrating the example embodiments.

FIG. 1 is a schematic drawing illustrating example scenarios for some embodiments;

FIGS. 2-7 are flowcharts illustrating various example methods according to some embodiments;

FIGS. 8-9 are signaling diagrams illustrating various example signaling according to some embodiments;

FIGS. 10-11 are schematic block diagrams illustrating example transmitters according to some embodiments;

FIG. 12 is a circuit diagram illustrating example oscillation and tapping circuitry according to some embodiments;

FIG. 13 is a schematic block diagram illustrating an example integrated circuit according to some embodiments;

FIG. 14 is a schematic block diagram illustrating an example apparatus according to some embodiments;

FIG. 15 is a schematic block diagram illustrating an example apparatus according to some embodiments; and

FIG. 16 is a schematic drawing illustrating an example computer readable medium according to some embodiments.

### DETAILED DESCRIPTION

As already mentioned above, it should be emphasized that the term “comprises/comprising” (replaceable by “includes/including”) when used in this specification is taken to specify the presence of stated features, integers, steps, or components, but does not preclude the presence or addition of one or more other features, integers, steps, components, or groups thereof. As used herein, the singular forms “a”, “an” and “the” are intended to include the plural forms as well, unless the context clearly indicates otherwise.

Embodiments of the present disclosure will be described and exemplified more fully hereinafter with reference to the accompanying drawings. The solutions disclosed herein can, however, be realized in many different forms and should not be construed as being limited to the embodiments set forth herein.

The present disclosure relates generally to the field of wireless communication. More particularly, it relates to monitoring and control of communication devices, as well as to transmitters operating with restricted power consumption.

Generally, restricted power consumption may be defined as power consumption below a power consumption threshold. Alternatively or additionally, when a transmitter is comprised in a communication device which also comprises a default transceiver, restricted power consumption of the transmitter may be defined as power consumption which is (typically substantially) lower than the (e.g., average) power consumption of the default transceiver.

Also generally, a default transceiver of a communication device may be defined as a transceiver which is most commonly used for communication by the communication device. For example, the default transceiver may be a transceiver configured to receive and/or transmit communication compliant with one or more communication standards (e.g., as advocated by the Third Generation Partnership Project, 3GPP; the IEEE; the Bluetooth Special interest Group, BT SIG; etc.). Alternatively or additionally, the default transceiver may be a transceiver configured to receive and/or transmit relatively complex signals (e.g., orthogonal frequency division multiplex, OFDM, signals; multiple-input multiple-output, MIMO, signals; etc.). Yet alternatively or additionally, the default transceiver may be a transceiver configured to receive and/or transmit signals modulated with other modulation than on-off keying (OOK) and/or frequency shift keying (FSK). Yet alternatively or additionally, the default transceiver may be a transceiver configured to receive and/or transmit signals at a data rate (or throughput) which is higher than a data rate (or throughput) threshold.

It is typically beneficial for a network to have information regarding communication devices operating in the network (e.g., particulars of the radio link between the communication device and the network, location information for the communication device, etc.).

However, there are scenarios when the network has very little information regarding the current circumstances of a communication device. For example, when a communication device (e.g., a user equipment, UE) is in sleep mode, the network in which the communication device operates typically has very little information regarding the current circumstances of the communication device.

Generally, a communication device being in sleep mode may include any suitable low activity mode(s) and/or power saving mode(s).

An example implementation of sleep mode for a communication device includes that a transceiver of the communication device is put in a low activity mode in which it does not transmit, but receives signals to determine that signals from the network can still be received. Such an example sleep mode may be referred to as a camping state, wherein the device is repeatedly monitoring signals to evaluate if the network is available, and/or to determine whether the network intends to reach the device for upcoming communication.

Alternatively or additionally, an example implementation of sleep mode for a communication device includes that a default transceiver of the communication device is put in an inactive mode in which it neither receives nor transmits any signals (e.g., turning off the default transceiver completely, or operating it at a relatively low power consumption to maintain an internal state and/or to enable fast transition to an active mode). A wake-up receiver (WUR) of the communication device may be configured to be operative while the default transceiver is in the inactive mode (e.g., to monitor wake-up signal, WUS, and wake up the default transceiver responsive to detection of a WUS for the communication device).

Typically, a WUR may be capable of detecting (e.g., receiving and distinguishing between) different sequences representing different wake-up signals. As will be elaborated in the following, a WUR may also be utilized to detect signals with other purposes than wake-up (e.g., a deep sleep monitoring, DSM, request). Such signals may be represented by further different sequences.

To achieve detection, the WUR may perform correlation with the different sequences in digital correlators. The WUR may comprise a single correlator configured for correlation with all of the different sequences (one by one), or one correlator for each of the different sequences, or any intermediate number of correlators where at least one of the correlators is configured for correlation with two or more of the different sequences.

When the different sequences are modulated using OOK, the reception may be implemented by performing—for each received symbol—amplitude detection (rectification) and comparison of the detected amplitude with a threshold value (e.g., half the expected amplitude of an ON-symbol) to determine the received symbol. Then, the sequence of received symbols may be processed by a digital correlator to determine whether or not a signal carrying the corresponding sequence is detected.

In some embodiments, filtering may be employed in the WUR (before and/or after the rectification) to limit the signal bandwidth and, thereby, the noise level.

In some embodiments, frequency down-conversion may be performed before the rectification. This may be particularly suitable for a high sensitivity WUR.

It should be noted that there are other ways to implement the WUR, and that any suitable implementation may be used in relation to the disclosure herein.

Generally, a WUR may comprise (e.g., consist of) one or more WUR hardware components and a default transceiver may comprise (e.g., consist of) one or more default transceiver hardware components. In some embodiments, all of the WUR hardware component(s) are different from the default transceiver hardware component(s). In some embodiments, some of the WUR hardware component(s) are different from the default transceiver hardware component(s), and some of the WUR hardware component(s) are also default transceiver hardware component(s). In some embodiments, all of the WUR hardware component(s) are also default transceiver hardware component(s). In the latter two cases, the default transceiver may be configured in either of a default transceiver mode and a WUS detection mode.

Some example sleep modes include inactive modes (e.g., RRC_INACTIVE), idle modes (e.g., RRC_IDLE), non-reception portions of discontinuous reception (DRX) modes, off-durations of discontinuous reception (DRX) modes, dormancy modes (e.g., secondary cell, SCell, dormancy in carrier aggregation, CA, scenarios), etc. In some embodiments, any non-connected mode may be considered as a sleep mode.

The lack of information at the network side regarding the current circumstances of a communication device in sleep mode may, for example, include that particulars of the radio link between the communication device and the network may be unknown and/or that location information for the communication device may be very imprecise. This may lead to impairment of initial communications after the sleep mode.

For example, suboptimal settings may be used for power, modulation, and coding since particulars of the radio link are unknown. This may, in turn, lead to decreased throughput. For example, decreased throughput may be caused because retransmissions are needed when the radio link quality is overestimated (using lower power than required and/or a modulation and coding order which is less robust than suitable for the radio link). Alternatively or additionally, decreased throughput may be caused because excessive interference is created when the radio link quality is underestimated (using higher power than necessary). Yet alternatively or additionally, decreased throughput may be caused because the information rate is lower than possible when the radio link quality is underestimated (using a modulation and coding order which is more robust than suitable for the radio link).

Alternatively or additionally, there may be a delay before the initial communication after sleep mode can commence. For example, such a delay may be due to that it takes some time to determine which radio access node should be used to serve the communication device when the location information is imprecise. Some embodiments address these problems by providing alternative approaches for monitoring of communication devices.

Furthermore, it is typically beneficial for a network to be able to control communication devices operating in the network, which typically requires that a communication device in sleep mode leaves the sleep mode to listen for signaling from the network. Alternatively, if wake-up signaling is employed by the network, a WUR may be employed in the communication device to avoid leaving sleep mode to listen for WUS signaling from the network. However, when a WUS for the communication device is detected, the communication device is typically required to leave the sleep mode to act on the signaling from the network (e.g., to transmit a response to the WUS, to monitor/receive other signaling than WUS, to perform a connection procedure, etc.).

Such activities entail power consumption by the communication device that may be undesirable. Furthermore, control signaling from the network entails overhead which may be undesirable.

Some embodiments address these problems by providing alternative approaches for controlling communication devices.

Transmitters operating with restricted (e.g., relatively low) power consumption are provided according to some embodiments. For example, such transmitters may be used for transmission from the communication device while the communication device remains in sleep mode. More generally, the suggested transmitters may be beneficial in any communication scenario where power consumption is of concern, and particularly when the power source of a communication device is limited.

An advantage of some embodiments is that improved monitoring of communication devices is provided. Particularly, monitoring of communication devices in sleep mode is enabled.

An advantage of some embodiments is that radio link monitoring is enabled for a communication device in sleep mode.

An advantage of some embodiments is that location monitoring is enabled for a communication device in sleep mode.

An advantage of some embodiments is that some data may be transmitted from a communication device in sleep mode.

An advantage of some embodiments is that information regarding a communication device may be maintained.

An advantage of some embodiments is that the monitoring of communication devices can be flexibly adjusted.

An advantage of some embodiments is that improved controlling of communication devices is provided.

An advantage of some embodiments is that signaling to/from a communication device in sleep mode can be flexibly adjusted.

An advantage of some embodiments is that transmitters operating with restricted (e.g., relatively low) power consumption are provided. For example, a transmitter disclosed herein may be able to transmit a signal with lower power consumption than other transmitters (e.g., other transmitters of a similar signal).

An advantage of some embodiments is that transmitters are provided which can be implemented with relatively small circuit area.

An advantage of some embodiments is that transmitters are provided which are suitable for operation during sleep mode of a communication device in which the transmitter is comprised.

An advantage of some embodiments is that signal transmission by a low power transmitter may be performed with relatively low frequency error (e.g., compared to other transmitters with similar power consumption). This entails that the signal may be received with relatively high accuracy.

Approaches are known in which a network transmits a wake-up signal (WUS), which is detectable by a wake-up receiver (WUR; a.k.a. wake-up radio), for prompting a communication device to leave sleep mode. For example, wake-up signaling approaches have been included in IEEE802.11 specifications as well as in 3GPP specifications (see, e.g., 3GPP technical specification TS 36.300, section 10.1.4). Such approaches allow the communication device to enter a state of low power consumption (e.g., a deep sleep mode) during idle mode operation.

During the deep sleep mode, the communication device typically performs WUS monitoring (e.g., using a WUR), which can be achieved with very low power consumption. Typically, a WUR may be implemented in a communication device using very low power consumption hardware, which is separate from the hardware of the default transceiver of the communication device. Thereby, the communication device is reachable in deep sleep mode while still preserving power.

When a WUS is detected for the communication device, the communication device leaves the sleep mode. For example, when the WUR detects a WUS for the communication device, it may be configured to trigger the communication device to leave the sleep mode by waking up the default transceiver.

There are some problems related to known wake-up signaling approaches. Some embodiments address one or more of these problems.

For example, there is no network-based radio link monitoring or precise location tracking while the communication device is in sleep mode. For the network to obtain information regarding the current circumstances of a communication device in sleep mode, the network typically needs to send a WUS to wake-up the communication device, which causes increased power consumption at the device.

Thus, existing wake-up signaling approaches are not suitable for measuring/reporting radio link quality and/or location tracking in a power efficient manner. Having information regarding radio link quality and/or location available at the network may be beneficial, for example, when channel conditions are variable and/or in mobility scenarios.

Generally, mobility scenarios may include that the communication device is mobile and/or that a relay node between the communication device and the network is mobile.

Also, there is no possibility in existing wake-up signaling approaches for a communication device to acknowledge WUS detection in a power efficient manner.

Furthermore, when a communication device refrains from WUS monitoring (e.g., because of an extreme power save scenario), the network may still transmit (and retransmit) WUS to attempt waking up of the device. This is problematic since the WUS transmission causes signaling overhead without achieving anything. Also, there is no possibility for the network to wake up the communication device in these scenarios. Ideally, it would be beneficial if it was possible to differentiate the wake-up functionality; e.g., such that a communication device could either be woken up for any of many purposes (e.g., for measurements, reporting, tracking, etc.), or for only a limited amount of purposes (e.g., to receive a paging signal). Thus, a mechanism is desired where a communication device is not disturbed (e.g., woken up) unless it is critical for some reason that it wakes up.

An example situation when a communication device typically refrains from WUS monitoring is during time periods when the communication device is not monitoring paging (e.g., during a so-called Power Save Mode (PSM), and during inactive periods of extended discontinued reception (DRX)).

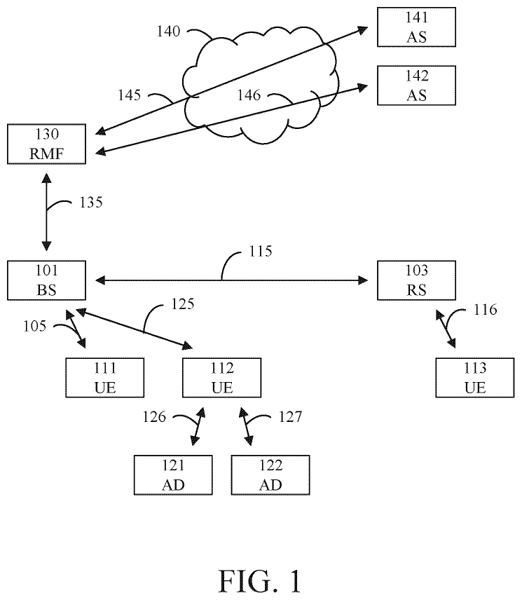

FIG. 1 schematically illustrates example scenarios which are relevant for some embodiments. In FIG. 1, a radio access network is represented by a base station (BS) 101.

A first communication device is represented by a user equipment (UE) 111, and communication between the BS 101 and the UE 111 is illustrated by 105. Some embodiments relate to a situation where the UE 111 is in sleep mode and the BS 101 monitors and/or controls the UE 111 when it is in sleep mode.

A second communication device is represented by a user equipment (UE) 112, and communication between the BS 101 and the UE 112 is illustrated by 125. The UE 112 acts as a relay node for some further communication devices represented by auxiliary devices (AD) 121, 122. Communication between the UE 112 and the AD 121 is illustrated by 126, and communication between the UE 112 and the AD 122 is illustrated by 127. For example, an auxiliary device may be a wearable device (e.g., a connected watch, a pair of virtual/augmented reality glasses, a connected glove, an electronic shackle, etc.), a control device (e.g., a computer mouse, a keyboard, a gaming console, etc.), a tool (e.g., a connected cutting/drilling device, a connected painting device, etc.), a measurement device (e.g., a connected stethoscope or other connected medical device, a connected tape measure, etc.), an Internet-of-Things (IoT) device, etc. Some embodiments relate to a situation where one or more of the ADs 121, 122 are in sleep mode and have delegated at least some sleep mode tasks to the UE 112, and the BS 101 monitors and/or controls the ADs 121, 122 in sleep mode via the UE 112.

A third communication device is represented by a user equipment (UE) 113, and communication between the BS 101 and the UE 113 takes place via a relay station (RS) 103 of the network. Communication between the BS 101 and the RS 103 is illustrated by 115, and communication between the RS 103 and the UE 113 is illustrated by 116. The RS 103 acts as a relay node for the UE 113. Some embodiments relate to a situation where the UE 113 is in sleep mode and has delegated at least some sleep mode tasks to the RS 103, and the BS 101 monitors and/or controls the UE 113 in sleep mode via the RS 103.

Generally, the network may utilize wake-up signaling on inactive radio links to enable lowering of the power consumption for communication devices. Wake-up signaling can be used on direct links with base stations (a.k.a. Uu interface in 3GPP), as exemplified by 105 in FIG. 1, and on sidelink communication links (a.k.a., PC5 in 3GPP), as exemplified by 126, 127, 116 in FIG. 1.

Using relay nodes may be particularly attractive to extend cellular network coverage for ultra-low power IoT-devices (e.g., wireless sensors). Thus, IoT-devices can be connected to a relay node which is more powerful than the IoT-devices, and thereby able to transfer data over longer distances.

Generally, delegation by a communication device of at least some sleep mode tasks to a relay node may include one or more different distributions of tasks between the communication device and the relay node. For example, the relay node may be responsible for monitoring WUS and/or deep sleep monitoring (DSM) requests for the communication device. Alternatively or additionally, the relay node may be responsible for transmitting WUS acknowledgements and/or DSM responses for the communication device. Yet alternatively or additionally, the relay node may be responsible for waking up the communication device when a WUS for the communication device is detected (possibly only when a high priority WUS is detected). The concept of DSM request and DSM response will be introduced and elaborated on later herein. As already mentioned, monitoring and/or controlling of communication devices in sleep mode may be particularly useful in mobility scenarios (e.g., when the communication device is mobile and/or when the relay node is mobile). When the communication device is mobile, the radio link between the communication device and the network/relay may vary (i.e., the most suitable parameters for communication may vary) and/or the location of the communication device may vary (i.e., the most suitable cell/beam for communication may vary). When the relay node is mobile, the radio link between the relay node and the network may vary, the radio link between the relay node and the communication device may vary, and/or the location of the communication device may vary. Furthermore, when the relay node and the communication device move away from each other (due to either, or both, being mobile) the relay node may become unavailable for the communication device. Then, the relay node may hand over the relaying tasks to another relay node (which is available for the communication device), or may prompt the communication device to switch to non-relayed operation.

FIG. 1 also illustrates a reachability management function (RMF) 130, and communication between the RMF 130 and the BS is illustrated by 135. The RMF may be implemented within the radio access network where the BS 101 operates (e.g., as a central function), or elsewhere. Furthermore, the RMF 130 may be implemented in a single location (e.g., in a dedicated server node) or may be distributedly implemented (e.g., in a cloud-like fashion).

The RMF 130 may be configured to maintain reachability information and/or monitoring statistics regarding communication devices based on reporting from the radio access network (e.g., from the BS 101). Alternatively or additionally, the RMF 130 may be configured to trigger a search for a communication device when the BS 101 reports it as unreachable. Yet alternatively or additionally, the RMF 130 may be configured to provide reachability information and/or monitoring information regarding communication devices to the BS 101 (e.g., information regarding how a communication device should be monitored and/or controlled in sleep mode, and/or what measures should be taken if the communication device becomes unreachable, and/or information derived from previous monitoring of the communication device).

The RMF 130 may (e.g., via the Internet 140) be operatively associated with one or more application servers (AS) 141, 142. Communication between the RMF 130 and the AS 141 is illustrated by 145, and communication between the RMF 130 and the AS 142 is illustrated by 146. In some embodiments, one or more of the ASs 141, 142 may comprise the reachability information and/or monitoring statistics regarding communication devices as maintained and/or accessible by the RMF 130.

In some embodiments, the information of an AS (e.g., regarding how a communication device should be monitored and/or controlled in sleep mode, and/or what measures should be taken if the communication device becomes unreachable) relates to a specific application on the communication device. Different applications on the communication device may be related to different such information (possibly comprised in different ASs. For example, a time critical medical application may be associated with relatively frequent monitoring in sleep mode and/or immediate search if reported as unreachable, while an entertainment application may be associated with relatively infrequent monitoring in sleep mode and/or no searching in sleep mode if reported as unreachable.

A problem with a communication device in sleep mode is that the network cannot know whether or not the communication device is reachable unless it transmits a WUS (followed by paging) to wake up the communication device and cause it to perform signaling associated with leaving sleep mode (e.g., including one or more of: paging monitoring, random access, connection setup, etc.). For example in 3GPP, a WUS transmission is indicative of an upcoming paging occasion wherein the communication device can expect to receive a paging indication. Thereafter, the communication is expected to perform a random access procedure (e.g., to enter the radio resource control, RRC, connected state). This entails increased power consumption for the communication device, which may be undesirable.

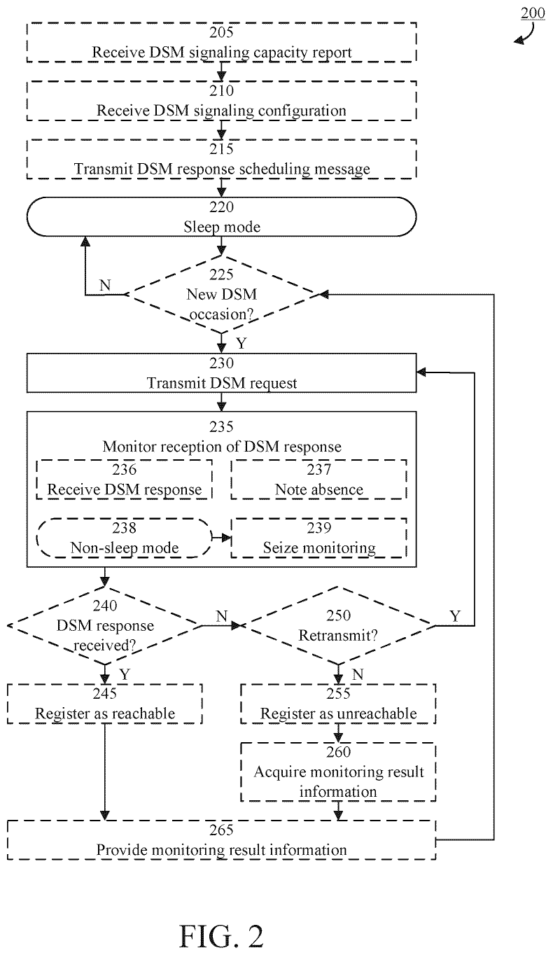

FIG. 2 illustrates an example method 200 according to some embodiments. The method 200 is for monitoring a communication device in sleep mode.

For example, the method 200 may be performed by the BS 101 of FIG. 1 to monitor one or more of: the UE 111, the UE 112, the UE 113 (via the RS 103), the AD 121 (via the UE 112), and the AD 122 (via the UE 112). Alternatively or additionally, the method 200 may be performed by any of the relay nodes of FIG. 1; i.e., by UE 112 to monitor the AD 121 and/or the AD 122, and/or by RS 103 to monitor UE 113. The method 200 may, for example, be used for monitoring a communication device (e.g., any of the communication devices UE 111, UE 112, UE 113, AD 121, and AD 122 of FIG. 1) comprising a default transceiver and a wake-up receiver (WUR), wherein the default transceiver is configured to be inactive when the communication device is in sleep mode and the WUR is configured to be operative when the communication device is in sleep mode.

While the communication device is in sleep mode, as illustrated by 220, the method 200 comprises transmitting a deep sleep monitoring (DSM) request to the communication device, as illustrated by step 230.

The DSM request is configured to trigger a DSM response by the communication device while the communication device remains in sleep mode. Thus, the DSM request is configured to trigger a DSM response by the communication device without transition by the communication device to a non-sleep mode (e.g., an active mode). For example, the DSM request may be configured to trigger a DSM response by the communication device without wake-up of the default transceiver.

In some embodiments, the DSM request is configured for detection by a WUR of the communication device. For example, the DSM request may have a similar structure as a wake-up signal (WUS). In some approaches, the DSM request comprises (e.g., consists of) a DSM symbol sequence modulated by on-off keying (OOK) or frequency shift keying (FSK). The WUR may comprise a correlator for the DSM symbol sequence and a corresponding peak detector for detecting the DSM request.

In some embodiments, the DSM request only carries the information that a DSM response is expected (e.g., only a single DSM symbol sequence is available). Alternatively, the DSM request may carry additional information (e.g., two or more DSM symbol sequences are available).

In the latter case, the DSM request may comprise scheduling information for the DSM response (e.g., period of time and/or frequency interval in which the DSM response is expected).

Alternatively or additionally, the DSM request may comprise identity information of transmitter node of the DSM request. Generally, the communication device may benefit from knowing/confirming the cell identity of the DSM request transmitter in a similar manner as it benefits from knowing/confirming the cell identity of broadcasted system information or other signaling from the network. In some embodiments, a separate node (other than the radio access node providing the cell; e.g., a relay node) may be used for DSM radio link monitoring (e.g., to ensure relatively low path loss between the communication device and the monitoring node). In such cases, the communication device may benefit from knowing the identity of the monitoring node (e.g., for mapping to a cell identity).

Yet alternatively or additionally, the DSM request may comprise identity information of the communication device (i.e., information regarding which communication device(s) is/are addressed by the DSM request). For example, identity information of the communication device may be implemented by the communication device having a DSM request sequence exclusively dedicated to it, or (if the communication device shares a DSM request sequence with communication devices) by an additional field for indicating communication device identity (e.g., UE ID).

Yet alternatively or additionally, the DSM request may comprise configuration information for the communication device. For example, the configuration information may comprise configuration parameters (e.g., for a default transceiver) which are expected to be applied directly when the communication device leaves sleep mode. A configuration confirmation (acknowledgement of configuration) may be expected from the communication device in response to the configuration information. The configuration information may be carried in an additional field of the DSM request (e.g., an 8-bit field) and the configuration confirmation may be carried in an additional field of the DSM response (e.g., a same-sized field). The configuration information and the configuration confirmation may be protected with mechanisms for error correction and/or error detection, according to some embodiments. In some embodiments, the DSM response is expected to re-confirm the latest configuration information when the field for configuration information is empty in the DSM request. For example, an empty field may be defined as containing a sequence that does not correspond to a valid sequence for configuration.

Yet alternatively or additionally, the DSM request may comprise conditioning for the DSM response (i.e., conditions that specify when the communication device is expected to provide the DSM response). For example, the DSM request may indicate that a DSM response is not expected when the communication device is stationary.

Yet alternatively or additionally, the DSM request may comprise an indication of expected content of the DSM response.

For example, the expected content of the DSM response may comprise one or more of: identity information of the communication device, acknowledgement of detection of the DSM request, acknowledgement of configuration (e.g., according to configuration information comprised in the DSM request) which may be in the form of a configuration report, radio link information (any suitable radio link information; e.g., received signal strength and/or quality for the DSM request, received signal-to-noise ratio for the DSM request, etc.), status information for the communication device (any suitable status information; e.g., transmission buffer status, battery status, etc.) which may be in the form of a device status report, status information for a sensor operatively connected to the communication device (any suitable status information; e.g., on/off status, operational mode, etc.), and data (e.g., data from a transmission buffer of the communication device, and/or sensor data).

For example, the received signal quality for the DSM request may be determined based on the correlator result. A relatively low received signal quality for the DSM request typically corresponds to a relatively high number of bit errors, which in turn corresponds to a relatively low correlation peak.

Typically, the amount of data that can be conveyed by a DSM response is very limited (e.g., smaller than a data amount threshold). Even so, it may be beneficial (e.g., for power consumption and/or signaling overhead) to be able to transmit some data when the communication device is in sleep mode (e.g., without waking up a default transceiver).

The method 200 further comprises monitoring reception of the DSM response, as illustrated by step 235 succeeding step 230.

For example, step 235 may comprise determining whether or not the DSM response is received within a period of time in which the DSM response is expected. Thus, step 235 may comprise receiving the DSM response (as illustrated by optional sub-step 236) or noting absence of the DSM response (as illustrated by optional sub-step 237).

If the communication device leaves sleep mode (as illustrated by 238), the monitoring of reception of the DSM response may be seized (i.e., aborted), as illustrated by optional sub-step 239. More generally, the DSM procedure exemplified by the method 200 (e.g., steps 225-265) may be aborted (as suitable) whenever the communication device leaves sleep mode.

The period of time in which the DSM response is expected may be expressed in absolute time or in relative time (e.g., relative the time for transmission of the DSM request). The DSM response may be expected in a time period directly subsequent to the transmission of the DSM request, or in a later time period.

In some embodiments, the period of time in which the DSM response is expected is implicitly defined, or defined by a DSM protocol (e.g., a DSM protocol of a communication standard, such as IEEE802.11 or 3GPP standards).

In some embodiments, the period of time in which the DSM response is expected is dynamically defined. For example, the DSM request may include an indication of the period of time in which the DSM response is expected, as already mentioned. Alternatively or additionally, a DSM response scheduling message may be transmitted to the communication device in preparation for sleep mode (as illustrated by optional step 215), wherein the DSM response scheduling message can indicate the period of time in which the DSM response is expected.

Monitoring the DSM response according to step 235 may comprise monitoring in a frequency interval where the DSM response is expected.

The frequency interval where the DSM response is expected may be expressed in absolute frequency or in relative frequency (e.g., relative the frequency for transmission of the DSM request).

In some embodiments, the frequency interval where the DSM response is expected is implicitly defined, or defined by a DSM protocol (e.g., a DSM protocol of a communication standard, such as IEEE802.11 or 3GPP standards).

In some embodiments, the frequency interval where the DSM response is expected is dynamically defined. For example, the DSM request may include an indication of the frequency interval where the DSM response is expected, as already mentioned. Alternatively or additionally, the DSM response scheduling message may indicate the frequency interval where the DSM response is expected.

Alternatively or additionally, the DSM response scheduling message may indicate other parameters for the DSM signaling (e.g., duration between different DSM requests, duration between DSM request retransmissions, etc.).

At the latest when the period of time in which the DSM response is expected has lapsed, the method 200 may proceed to optional step 240, where it is determined whether the DSM response was received.

When the DSM response has been received (Y-path out of step 240), the method 200 may comprise registering the communication device as reachable as illustrated by optional step 245. When the DSM response has not been received (N-path out of step 240), i.e., when absence of the DSM response has been noted, the method 200 may proceed to optional step 250, where it is determined whether or not the DSM request should be retransmitted.

When the DSM request should be retransmitted (Y-path out of step 250), the method returns to step 230. When the DSM request should not be retransmitted (N-path out of step 250), the method 200 may comprise registering the communication device as unreachable as illustrated by optional step 255.

For example, the DSM request may be retransmitted up to a maximum number of times (which may be fixed or dynamically adjustable) as long as the DSM response is not received. In some embodiments, the maximum number of times is zero and step 250 may be omitted such that the N-path out of step 240 leads directly to step 255.

During sleep mode, several DSM requests may be transmitted, as illustrated by the looping through optional step 225. When a new DSM occasion is reached (Y-path out of step 225), the method 200 proceeds to step 230 for transmission of a new DSM request. In between DSM occasions (N-path out of step 225), the method 200 is lingering as long as no other step (e.g., monitoring in step 235 or retransmission in step 230) is being executed.

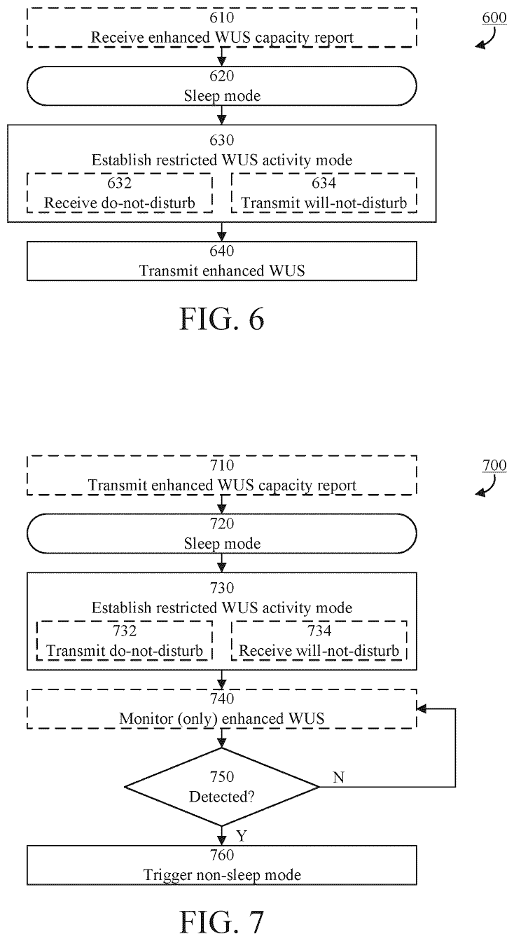

As will be elaborated on further in connection with FIGS. 6 and 7, the DSM response may comprise a do-not-disturb indication. Then, the method 200 may comprise refraining from any further DSM request transmission and/or retransmission. Thus, when the DSM response comprises a do-not-disturb indication, the DSM procedure exemplified by the method 200 may be aborted (as suitable). In some embodiments, a do-not-disturb indication may be received from the communication device already in preparation for sleep mode, in which case the DSM procedure exemplified by the method 200 is typically not executed at all.

Before the sleep mode of the communication device (e.g., during a registration process of the communication device, and/or in preparation for sleep mode, and/or at any suitable time when the communication device is in connected mode), the method 200 may comprise receiving a DSM signaling capacity report from the communication device, as illustrated by optional step 205.

The DSM signaling capacity report may indicate whether the communication device is capable of DSM request detection and/or DSM response transmission. In some embodiments, the DSM signaling capacity report may also indicate other DSM capabilities (e.g., what type of information the communication device is capable of including in a DSM response).

The transmission of the DSM request in step 230 may be conditioned on reception of the DSM signaling capacity report. For example, if no DSM signaling capacity report has been received, it may be assumed that the communication device is not capable of DSM request detection and/or DSM response transmission, and the DSM procedure exemplified by the method 200 (i.e., steps 210-265) is typically not executed at all.

The method 200 may also comprise receiving a DSM signaling configuration, as illustrated by optional step 210. The DSM signaling configuration may be comprised in the DSM signaling capacity report, or may be received as a separate message. When received in a separate message, the DSM signaling configuration might be received more often than the DSM signaling capacity report. For example, the DSM signaling capacity report may be received during a registration process of the communication device, while the DSM signaling configuration may be received in preparation for sleep mode.

The DSM signaling configuration may indicate any information that is suitable for the DSM procedure.

For example, the DSM signaling configuration may indicate whether or not DSM is to be used (e.g., in the form of a DSM-flag indicating on/off, or a do-not-disturb indication to turn off DSM). When the DSM signaling configuration indicates that DSM is not to be used, the DSM procedure exemplified by the method 200 (i.e., steps 215-265) is typically not executed at all. Furthermore, the DSM signaling configuration may indicate when the DSM is to be turned on and/or off. For example, a do-not-disturb indication may be supplemented by a timer value indicating when the communication device intends to start listening to DSM requests again. Alternatively or additionally, conditions may be indicated for turning the DSM signaling off (e.g., when low battery is reported) or on (e.g., when mobility is reported).

Alternatively or additionally, the DSM signaling configuration may indicate any parameters similar to those mentioned above for the DSM response scheduling message. For example, the DSM signaling configuration may indicate one or more of: desired time period for DSM response, desired frequency interval for DSM response, desired duration between different DSM requests, desired duration between DSM request retransmissions, etc. In such embodiments, the DSM signaling configuration may be used instead of the DSM response scheduling message, or both messages may be used (e.g., indicating different parameters, or the DSM response scheduling message confirming—or adjusting—the desired parameter values of the DSM signaling configuration).

Yet alternatively or additionally, the DSM signaling configuration may indicate the maximum number of retransmissions of a DSM request (e.g., before registering the communication device as unreachable).

Yet alternatively or additionally, the DSM signaling configuration may indicate one or more other triggering conditions than absence of DSM response (e.g., threshold values for any suitable radio link information; e.g., received signal strength for the DSM request/response, received signal-to-noise ratio for the DSM request/response, etc.). For example, each condition may be associated with a corresponding action.

Yet alternatively or additionally, the DSM signaling configuration may indicate one or more actions to trigger responsive to absence of DSM response and/or one or more other triggering conditions. Example actions include registering the communication device as unreachable, triggering a search for a communication device, paging the communication device, transmitting a WUS (possibly a high priority WUS) to the communication device, triggering another network node to page the communication device, triggering another network node to transmit a WUS (possibly a high priority WUS) to the communication device, and triggering another network node to transmit a DSM request to the communication device.

In some embodiments, the method 200 also comprises interaction with a monitoring manager node. For example, the monitoring manager node could correspond to the RMF 130 as described in connection with FIG. 1.

In some embodiments, interacting with the monitoring manager node comprises receiving the DSM signaling capacity report of step 205 and/or the DSM signaling configuration of step 210 from the monitoring manager node instead of (or in addition to) from the communication device. For example, the reception step 210 may comprise receiving an instruction from the monitoring manager node to transmit a DSM request to a communication device (e.g., due to that it has be registered as unreachable by another network node).

Alternatively or additionally, the DSM signaling configuration of step 210 (regardless if received from the communication device or from the monitoring manager node) may comprise indications regarding whether—and to what extent—DSM particulars (e.g., reachability and/or content of the DSM response) should be shared by the monitoring manager node, and/or an identifier of the monitoring manager node and/or application server.

In some embodiments, interacting with the monitoring manager node comprises providing monitoring result information (e.g., reachability and/or content of the DSM response) to the monitoring manager node, as illustrated by optional step 265.

In some embodiments, interacting with the monitoring manager node comprises acquiring monitoring result information from the monitoring manager node responsive to noting absence of the DSM response (as illustrated by optional step 260), or responsive to not transmitting DSM requests (e.g., when DSM is off; due to a do-not-disturb indication or any other reason).

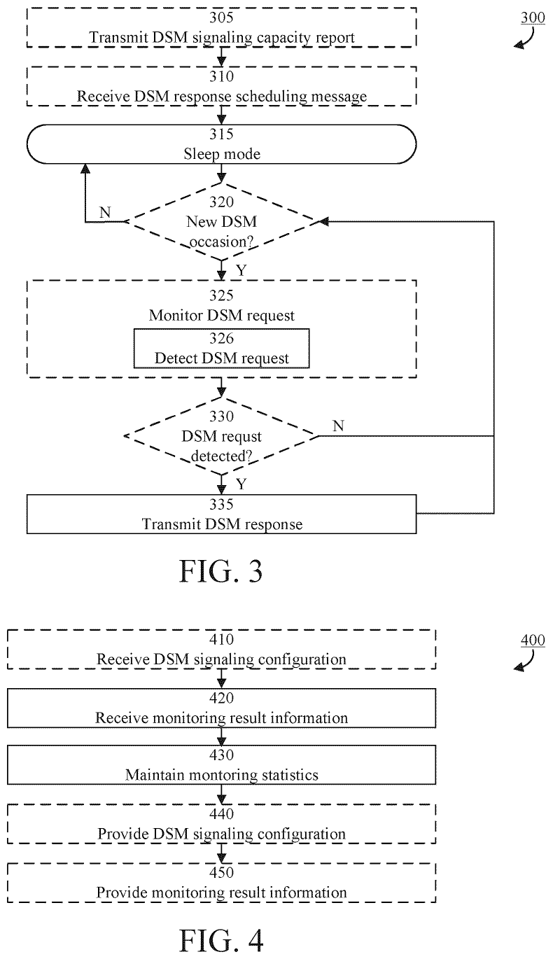

FIG. 3 illustrates an example method 300 according to some embodiments. The method 300 is for a communication device in sleep mode.

For example, the method 300 may be performed by one or more of: the UE 111, the UE 112, the UE 113, the AD 121, and the AD 122 of FIG. 1; during monitoring by the BS 101 and/or any of the relay nodes of FIG. 1.

Alternatively or additionally, the method 300 may be performed by a communication device while monitored by a node performing the method 200 of FIG. 2.

The method 300 may, for example, be performed by a communication device comprising a default transceiver and a wake-up receiver (WUR), wherein the default transceiver is configured to be inactive when the communication device is in sleep mode and the WUR is configured to be operative when the communication device is in sleep mode. The WUR may be implemented in any suitable way (e.g., as commonly implemented for WUS detection).

While the communication device is in sleep mode, as illustrated by 315 (compare with 220 of FIG. 2), the method 300 comprises detecting a deep sleep monitoring (DSM) request, as illustrated by 326 (compare with step 230 of FIG. 2). For example, the DSM request may be detected by a WUR of the communication device. Other features and examples of the DSM request are derivable from the description in connection to FIG. 2.

In some embodiments, the method 300 comprises monitoring DSM requests (as illustrated by optional step 325), and the detection of the DSM request is accomplished during the DSM request monitoring (as illustrated by 326 being a sub-step of optional step 325).

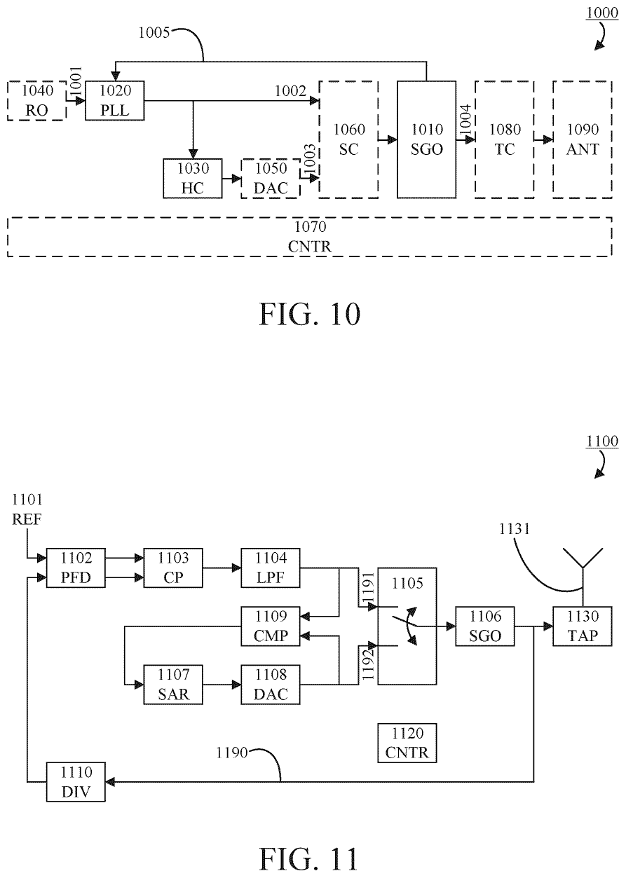

The method 300 also comprises transmitting a DSM response while remaining in sleep mode, as illustrated by step 335 (compare with steps 235, 236 of FIG. 2). Thus, the DSM response is transmitted by the communication device without transition by the communication device to a non-sleep mode (e.g., an active mode). For example, the DSM response may be transmitted by the communication device without wake-up of the default transceiver. Transmitters suitable for this purpose will be described later herein, in connection with FIGS. 10-13.

In some embodiments, the DSM response is configured to be transmitted at relatively low power consumption and/or by a relatively simple transmitter. Alternatively or additionally, the DSM response is configured to be received without accurate time and/or frequency synchronization. For example, the DSM response may have a similar structure as a wake-up signal (WUS). In some approaches, the DSM response is modulated using on-off keying (OOK) or frequency shift keying (FSK).

Typically, the DSM response transmission is in correspondence with the DSM request (e.g., regarding content of the DSM response, a period of time in which the DSM response is expected, and a frequency interval where the DSM response is expected). Other features and examples of the DSM response are derivable from the description in connection to FIG. 2. For example, the DSM response may comprise a do-not-disturb indication.

Also typically, step 325 may comprise DSM request monitoring during time periods and/or on frequencies where DSM requests are expected.

During sleep mode, there may be several time periods where DSM requests may be expected, as illustrated by the looping through optional step 320. When a new DSM occasion is reached (Y-path out of step 320), the method 300 proceeds to step 325 for DSM request monitoring. In between DSM occasions (N-path out of step 320), the method 300 is lingering as long as no other step (e.g., monitoring in step 325 or transmission in step 335) is being executed.

At the latest when a time period where DSM requests are expected has lapsed, the method 300 may proceed to optional step 330, where it is determined whether any DSM request was detected.

When a DSM request has been detected (Y-path out of step 330), the method 300 proceeds to step 335 for transmission of the DSM response. When no DSM request has been detected (N-path out of step 330), as well as after transmission of the DSM response in step 335, the method 300 may loop back to step 320 as described above.

Generally, it should be noted that the DSM procedure exemplified by the method 300 (e.g., steps 320-335) may be aborted (as suitable) whenever the communication device leaves sleep mode.

Before the sleep mode of the communication device (e.g., during a registration process of the communication device, and/or in preparation for sleep mode, and/or at any suitable time when the communication device is in connected mode), the method 300 may comprise transmitting a DSM signaling capacity report, as illustrated by optional step 305 (compare with step 205 of FIG. 2). Features and examples of the DSM signaling capacity report are derivable from the description in connection to FIG. 2.

Even if not illustrated in FIG. 3, the method 300 may also comprise transmitting a DSM signaling configuration (compare with step 210 of FIG. 2). Features and examples of the DSM signaling configuration are derivable from the description in connection to FIG. 2.

Before the sleep mode of the communication device (e.g., in preparation for sleep mode, and/or at any suitable time when the communication device is in connected mode), the method 300 may comprise receiving a DSM response scheduling message, as illustrated by optional step 310 (compare with step 215 of FIG. 2). Features and examples of the DSM response scheduling message are derivable from the description in connection to FIG. 2.

Generally, DSM request and DSM response may be seen as layer 1 signaling (e.g., in the context of 3GPP).

Also generally, DSM request and DSM response may be seen as a way to enable two-way confirmation of the inactive radio link of a communication device.

In the context of 3GPP, the DSM response scheduling message may, for example, be provided via RRC configuration signaling and/or via downlink control information.

Also in the context of 3GPP, the DSM signaling capacity report may, for example, be provided via UE capability signaling.

Generally, the communication device may also provide a recommendation regarding when the DSM protocol should be used. In the context of 3GPP, such a recommendation may, for example, be provided via RRC signaling of UE assistance information.

FIG. 4 illustrates an example method 400 according to some embodiments. The method 400 is for a monitoring manager node, wherein the monitoring manager node is configured to manage monitoring of one or more communication devices during communication device sleep mode.

For example, the method 400 may be performed by the RMF 130 of FIG. 1 in association with monitoring of one or more of: the UE 111, the UE 112, the UE 113 (via the RS 103), the AD 121 (via the UE 112), and the AD 122 (via the UE 112). Alternatively or additionally, the method 400 may be performed in conjunction with another node (e.g., the BS 101 of FIG. 1) performing the method 200 of FIG. 2.

For one or more of the monitored communication devices, the method 400 comprises receiving monitoring result information for the specific communication device, as illustrated by step 420 (compare with step 265 of FIG. 2). The monitoring result information may comprise any suitable information associated with the monitoring of a communication device (e.g., any suitable information associated with DSM signaling). For example, the monitoring result information may comprise one or more of: information that the communication device is reachable, information that the communication device is unreachable, a requested action when the communication device is unreachable, and any suitable information conveyed by a DSM response from the communication device (e.g., particulars of the radio link between the communication device and the network).

The method 400 also comprises maintaining monitoring statistics for one or more of the monitored communication devices based on received monitoring result information, as illustrated by step 430. The monitoring statistics may be any suitable statistics associated with the monitoring of a communication device (e.g., any suitable statistics associated with DSM signaling). For example, the monitoring statistics may comprise one or more of: reachability statistics, location statistics, statistics related to information conveyed by DSM responses (e.g., radio link statistics).

In some embodiments, the method 400 may comprise providing a DSM signaling configuration for a communication device, as illustrated by optional step 440 (compare with step 210 of FIG. 2). In these embodiments, the method 400 may also comprise receiving a DSM signaling configuration for a communication device, as illustrated by optional step 410. For example, the DSM signaling configuration for a communication device may be received from the communication device, from a base station or relay node that monitors the communication device, or from an application server. Alternatively, the DSM signaling configuration for a communication device may be determined by the monitoring manager node.

In some embodiments, the method 400 may comprise providing monitoring result information for a communication device, as illustrated by optional step 450 (compare with step 260 of FIG. 2). Typically, the provided monitoring result information is based on previous monitoring result information for the communication device (e.g., as received in step 420) and/or monitoring statistics for the communication device (e.g., as maintained in step 430). Step 450 may, for example, be beneficial when the previous monitoring result information is useful for determining a context of the device. Such context may be indicative of a location of the device or a mobility information of the device or a signal strength of the radio communication link to or from the device.

General network controlled device reachability management will now be described and exemplified. In some embodiments, one or more steps of the method 400 may be included in the network controlled device reachability management. Alternatively or additionally, the network controlled device reachability management may involve the RMF 130, and possibly the application servers 141, 142, of FIG. 1.

One motivation for having network controlled device reachability management is that the network may be required to take decisions on whether or not (and how frequently) to monitor a communication device in sleep mode. Monitoring entails overhead signaling and power consumption for the communication device, so there is a trade-off between, on one hand, information acquisition via monitoring and, on the other hand, power consumption and signaling overhead.

One motivation for having network controlled device reachability management is that the network may share information on application level (e.g., basing monitoring on application particulars, differentiating monitoring based on which applications the communication device uses, etc.). For example, a configuration specifying whether or not (and how often) to monitor a communication device may be application driven (compare with steps 210, 410, 440 of FIGS. 2 and 4).

One motivation for having network controlled device reachability management is that the network may share information with nodes outside the network.

In legacy networks, a communication device in sleep mode (e.g., idle) is responsible for camping on a suitable cell, and for monitoring and measuring the cell broadcast to ensure that the received signal strength is good enough for continued camping. If the communication device determines that continued camping is not viable, it searches for neighbor cells and performs measurements to enable cell reselection. The legacy network has very little information about a communication device in idle mode. For example, the network will know neither the status of the radio link of the communication device, nor detailed location of the communication device.

Some embodiments of the DSM signaling presented herein addresses these issues. Some challenges addressed by network controlled device reachability management relate to determination of which communication devices should be configured to use DSM, and which action(s) should be taken when a communication device is unreachable (e.g., which action(s) should be taken when a communication device is relatively often unreachable).

Thus, there is a need for approaches that enable the network to be aware of (e.g., determine) which communication devices should have DSM enabled (and how frequently the DSM request should be transmitted).

Furthermore, there is a need for approaches for specifying which action(s) the network may take when the network is aware of a communication device in sleep mode with weak or non-working radio link. As will be exemplified in the following, monitoring statistics may be used in this context.

According to some embodiments related to network controlled device reachability management, a communication device operating in a network can provide a radio access node with information regarding its sleep mode reachability monitoring requirements (compare with DSM signaling capacity report and DSM signaling configuration described above). For example, the information may be conveyed as device assistance information (e.g., in 3GPP, the information may be conveyed via UE assistance information, UAI).

Generally, the information regarding sleep mode reachability monitoring requirements of a communication device may comprise any suitable information. For example, the information regarding sleep mode reachability monitoring requirements may comprise one or more of:
DSM configuration particulars. Examples include:
   A communication device DSM operation flag (e.g., indicating DSM on/off). The flag may be extended with a duration value that indicates for how long the current flag value is valid (e.g., valid for a current message, valid for a certain amount of time, etc.).
   Timing configurations indicating DSM occasion scheduling (e.g., how often the network should transmit DSM requests, and/or when the network should transmit DSM requests).
   An indication regarding what type of information may be included in a DSM response from a communication device (e.g., link measurement information, sensor data readout, etc.).
   Whether (and to what extent) DSM data may be shared; within and/or outside the network. For example, when weak radio link detecting or lost connection is detected for a communication device in sleep mode, the network could provide DSM monitoring data for the communication device to another node in the network. The DSM configuration may specify what type of information to provide. Alternatively or additionally, the DSM configuration may specify if the network should page the communication device for which weak radio link detecting or lost connection is detected.
   Trigger values specifying conditions for considering a link as weak or lost. Example trigger values relate to thresholds for signal strength, signal-to-noise ratio (SNR), DSM reception bit error rate (BER), timer values, etc.
   Specific DSM operation for situations when the battery charge is low for the communication device; as reported in a DSM response).
   Action(s) that should be performed when a link is considered weak, and/or when a link is lost.
An identifier (e.g., a uniform resource locator, a web address, an Internet protocol (IP) address, etc.) of an intended receiver of DSM information of the communication device (e.g., weak/lost link); e.g., the RMF.
An identifier (e.g. a uniform resource locator, a web address, an IP address, etc.) to secondary DSM information provider (e.g., when the communication device is unreachable, when monitoring statistics is required, etc.) ; e.g., the RMF. The secondary DSM information provider may, or may not, be implemented by the same node as the intended receiver of DSM information.

The network can use the information regarding sleep mode reachability monitoring requirements to support network decisions regarding DSM operation (e.g., whether or not to activate DSM for a particular communication device, whether or not to share information acquired via DSM signaling, etc.).

Thus, an approach is provided to enable a communication device to provide DSM signaling configuration particulars to the network, which enables higher layer (e.g., application level) interaction related to such configuration particulars. Furthermore, statistics and/or notifications may be provided to applications based on statistics of the DSM signaling.

Furthermore, network controlled device reachability management may be useful in the context of tracking the location of a communication device in sleep mode, as exemplified in the following.

Location sharing in sleep mode may be based on DSM. Since the DSM signaling can be used to ping a communication device while it is in sleep mode, a radio access node may be enabled to be aware of how many (and which) communication devices are camping within a geographical area (e.g., a radio cell). Using a common DSM signal, which all devices configured for DSM should monitor and respond to, a sleep mode tracking function may be enabled. Such location information may be reported to a managing node; e.g., the RMF.

In some embodiments, conditioning for responding to DSM requests may be provided. For example, only communication devices in a mobile scenario (e.g., determined via an accelerometer of the communication device) might be conditioned to transmit DSM responses. This may be particularly relevant for DSM requests that are transmitted for the purpose of location tracking.

The location tracking may be used by the network when a radio access node, where a communication device was previously camping, no longer receives DSM responses from that communication device. Then, one or more other radio access nodes may be triggered to transmit DSM requests to the communication device in order to potentially locate the communication device without triggering it to leave sleep mode.

In some embodiments, a relay node handling a collection of communication devices may request to activate DSM signaling for a group of communication devices in the collection. When DSM signaling is activated, the relay node can monitor whether or not the communication devices of the group are within a proximity of the relay node, even when the communication devices are in sleep mode. DSM monitoring by a relay node can be utilized for positioning of a communication device with very low power consumption for the communication device. The location of the relay node may be determined (e.g., using a satellite-based system, such as a Global Navigation Satellite System (GNSS), and/or network based positioning). The location of the relay node may be provided to the network (e.g., together with information of DSM responses from the communication device and/or beam information to approximate a direction from the relay node to the communication device), and a corresponding estimated location of the communication device may be stored in the RMF. Then, the RMF may be accessed for the latest available location of a communication device, without triggering the communication device to leave sleep mode.

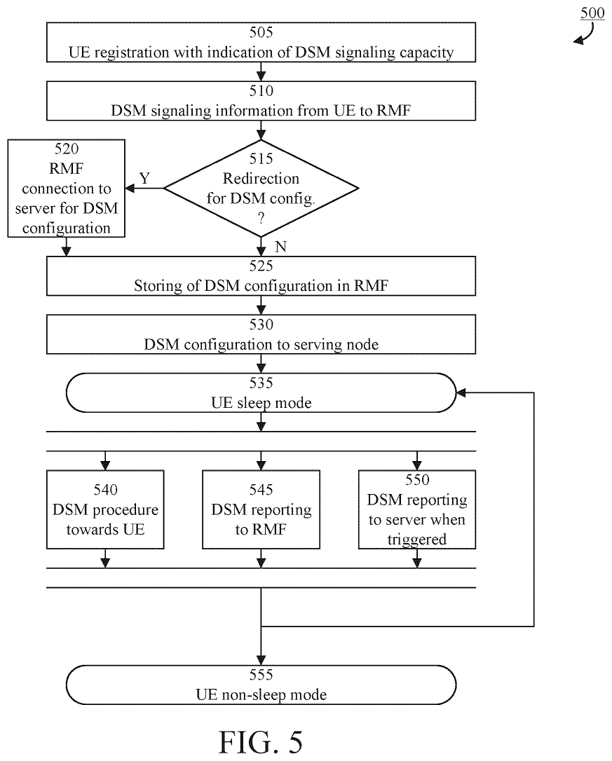

FIG. 5 illustrates an example method 500 according to some embodiments. The method 500 exemplifies operations related to the RMF (compare with the RMF 130 of FIG. 1).

In step 505, A UE registers to the network and indicates DSM signaling capability (compare with step 205 of FIG. 2, and step 305 of FIG. 3).

In step 510, the UE sends assistance information to the network (e.g., using RRC configuration), which is forwarded by the network to the RMF (compare with step 410 of FIG. 4). The assistance information may include DSM signaling information, such as a recommended/desired DSM signaling configuration.

In step 515, it is determined (e.g., by a radio access node) whether or not there is any redirection related to DSM configuration for a communication device (e.g., whether or not the DSM configuration of the communication device should be provided by another node than the communication device).

If so (Y-path out of step 515), the method proceeds to step 520, where the RMF connects to a server for the DSM configuration.

Regardless of whether the DSM configuration is provided by the communication device (N-path out of step 515) or from a server (step 520), the method proceeds to step 525, where the RMF stores the DSM configuration.

When the UE is entering into sleep mode (as illustrated by 535), the serving node for the UE receives the DSM configuration from the RMF, as illustrated by step 530 (compare with step 210 of FIG. 2).

While the UE is in sleep mode, the previously serving node performs the DSM procedure and DSM reporting to the RMF, as illustrated by steps 540 and 545 (compare with steps 230, 235, 265 of FIG. 2). When triggered, the RMF performs DSM reporting to an external server, as illustrated by step 550.

At least the DSM procedure and DSM reporting are terminated when the UE leaves sleep mode, as illustrated by 555.

According to some embodiments, the functionality related to the RMF may be divided into three aspects: UE indication to network of preferred DSM configuration, network managing and storing of DSM information, and network integration with application servers. Furthermore, some relay aspects may be applied in the context of the functionality related to the RMF.

### UE Indication to Network of Preferred DSM Configuration

The UE may provide DSM configuration information (e.g., suitable DSM parameters) to the network. Alternatively or additionally, the UE may provide information indicative of another node (e.g., an application server on the Internet) where DSM configuration information may be acquired.

For example, this type of UE signaling may be embedded within the procedure of UE registering to the network.

To enable the network to know whether the UE supports DSM signaling, the UE may provide a corresponding indication to the network as part of a UE capability signaling.

When the UE indicates support for DSM, the network may send a DSM configuration request to the UE, and the UE may respond with a DSM configuration message indicating DSM configuration information.

For example, this could be implemented via RRC signaling, or signaling on higher layers (e.g., IP data communication; for example, directly between an application entity in the device and a network entity communicating using the corresponding higher layer protocol).

Suitable DSM configurations may, for example, depend on how the UE is used (e.g., which applications and/or services are running on the UE), which may vary over time. For example, depending on the application, there can be very different requirements on whether or not the UE is required to be reachable all the time. In some embodiments, an application entity of the UE provides the modem entity of the UE with relevant information for reachability, and the modem entity provides corresponding DSM configuration information to the network.

Since the suitable DSM configuration may vary over time, the UE may transmit DSM configuration updates (e.g., via RRC configuration update signaling) to the network while the UE is connected to the network.

In a relay scenario, the relay node may activate DSM signaling with the relayed device(s), as well as provide the corresponding DSM assistance information to the network. The network may allocate communication resources to the relay node for DSM signaling according to the DSM assistance information.

### Network Managing and Storing of DSM Information

The reachability monitoring function (RMF) is proposed to store and manage DSM information for UEs within a network. Using the RMF, a network can be aware of which UEs in idle mode there are in the network, the UEs can be monitored via DSM signaling, and the network can be aware of DSM statistics by radio access nodes reporting to the RMF.

The RMF can provide radio access nodes with suitable DSM parameters for a certain UE (e.g., when the UE is mobile within the network).

The RMF may be a separate function within a network, or may be part of another function. For example in the context of 5G, the RMF may be included in 5G Core Access and Mobility Management Function (AMF), and/or in Session Management Function (SMF).

### Network Integration with Application Servers (e.g., on the Internet)

The RMF may be configured to interact with one or more application server functionality external from the network (e.g., Internet applications).

An application on the Internet may have device specific application layer context information, that is relevant for defining whether (and to what extent) a UE should be monitored via DSM signaling in idle mode.

An application on the Internet may be made aware of whether a UE is reachable or not, even if the UE is in idle mode within the network. For example, the reachability status can be provided by the RMF to one or more configured external nodes (e.g., application servers). The RMF may also provide location information for a UE to the application; while the UE remains in idle mode. Reachability information and/or location information may be provided upon request from an external server, or as regular updates from the RMF.

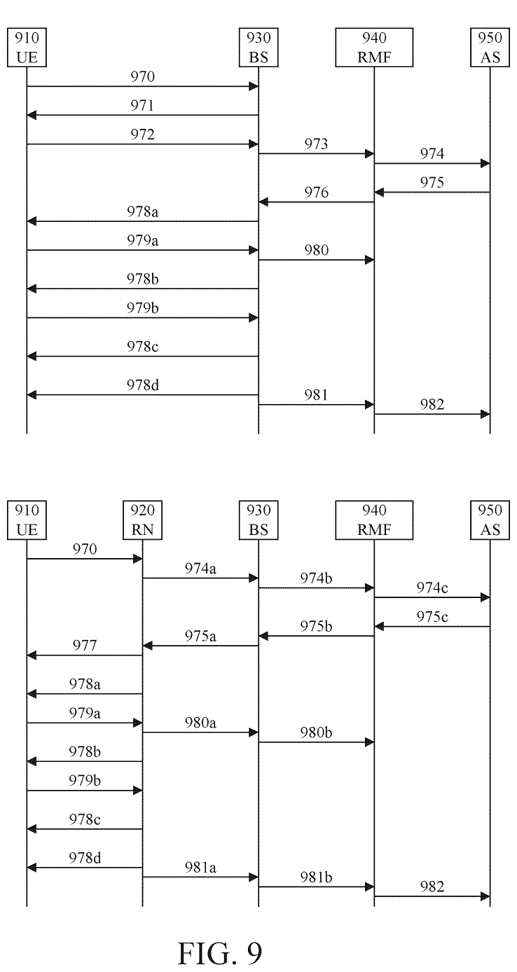

Some further exemplification of network controlled device reachability management will be provided later herein; in connection with FIG. 9.

Returning to the communication device in sleep mode, some various ways to control wake-up of a communication device will now be described and exemplified with reference to FIGS. 6 and 7.

FIG. 6 illustrates an example method 600 according to some embodiments. The method 600 is for controlling a communication device in sleep mode. For example, the method 600 may be suitable to control wake-up of a communication device.

For example, the method 600 may be performed by the BS 101 of FIG. 1 to control one or more of: the UE 111, the UE 112, the UE 113 (via the RS 103), the AD 121 (via the UE 112), and the AD 122 (via the UE 112). Alternatively or additionally, the method 600 may be performed by any of the relay nodes of FIG. 1; i.e., by UE 112 to control the AD 121 and/or the AD 122, and/or by RS 103 to control UE 113. Yet alternatively or additionally, the method 600 may be performed in combination with the method 200 of FIG. 2, according to some embodiments.

The method 600 may, for example, be used for controlling a communication device (e.g., any of the communication devices UE 111, UE 112, UE 113, AD 121, and AD 122 of FIG. 1) comprising a default transceiver and a wake-up receiver (WUR), wherein the default transceiver is configured to be inactive when the communication device is in sleep mode and the WUR is configured to be operative when the communication device is in sleep mode.

While the communication device is in sleep mode, as illustrated by 620, the method 600 comprises establishing a restricted wake-up signal, WUS, activity mode of the communication device, as illustrated by step 630.

Establishing the restricted WUS activity mode of the communication device may comprise receiving a do-not-disturb indication from the communication device, as illustrated by optional sub-step 632. For example, the do-not-disturb indication may be comprised in a DSM response from the communication device (compare with steps 235, 236 of FIG. 2), or in a DSM signaling configuration for the communication device (compare with step 210 of FIG. 2).

Alternatively or additionally, establishing the restricted WUS activity mode of the communication device may comprise transmitting a will-not-disturb indication to the communication device, as illustrated by optional sub-step 634. For example, the will-not-disturb indication may be comprised in a DSM request (compare with step 230 of FIG. 2), or in a DSM response scheduling message for the communication device. In some embodiments, the will-not-disturb indication is provided when the communication device is connected to the network (e.g., during an initial connection).

It should be noted that the reception of the do-not-disturb indication and/or the transmission of the will-not-disturb indication may be performed before the communication device enters into sleep mode, according to some embodiments.

The restricted WUS activity mode is configured to be applied when the communication device is in sleep mode. For example, the restricted WUS activity mode may be seen as a mode with restricted operation of the WUR (e.g., monitoring less signals and/or with lower accuracy than in its normal operation mode; a default WUS activity mode). Alternatively or additionally, the restricted WUS activity mode may be seen as a mode with restricted (e.g., no) transmissions during sleep mode. Yet alternatively or additionally, the restricted WUS activity mode may be seen as a mode with restricted wake up from sleep mode.

The restricted WUS activity mode can be defined as a mode where the communication device refrains from monitoring one or more signals other than an enhanced WUS (e.g., refrains from monitoring legacy WUSs, and/or WUS types with lower priority than the enhanced WUS, and/or DSM requests).

Alternatively or additionally, the restricted WUS activity mode can be defined as a mode where the communication device remains in sleep mode responsive to detection of one or more WUS types other than the enhanced WUS (e.g., legacy WUSs, and/or WUS types with lower priority than the enhanced WUS).

Yet alternatively or additionally, the restricted WUS activity mode can be defined as a mode where the communication device refrains from transmission of a DSM response responsive to detection of a DSM request.

The restricted WUS activity mode may be seen as a mode which contrasts to a default WUS activity mode. The default WUS activity mode can be defined as a mode where the communication device monitors all WUS types, and DSM requests (when applicable), leaves sleep mode responsive to detection of any WUS, and (when applicable) transmits a DSM response responsive to detection of a DSM request.

The method 600 also comprises transmitting an enhanced WUS (also referred to as a high priority WUS; HP-WUS) to the communication device, as illustrated by step 640.

For example, the enhanced WUS may be transmitted when it is critical for some reason that the communication device wakes up, while legacy WUS and/or WUS types with lower priority than the enhanced WUS are transmitted also for non-critical purposes. Example definitions of critical vs. non-critical in this context may, for example, be based on the QoS level of the data service (e.g., critical if QoS is above a threshold value, non-critical otherwise), and/or whether or not the upcoming data communication relates to end user (human) attended traffic (e.g., critical if requested by user input and/or causing rendering for a user, non-critical otherwise).

When the method 600 is performed by a relay node, the relay node may be configured to monitor all WUS types during the restricted WUS activity mode of a communication device, and transmit the enhanced WUS to the communication device only when a WUS is detected that is intended for the communication device.

The enhanced WUS is configured for detection by the communication device (e.g., by a WUR of the communication device) when the communication device is in the restricted WUS activity mode. For example, the enhanced WUS may have a similar structure as a default/legacy WUS. In some approaches, the enhanced WUS comprises (e.g., consists of) an enhanced WUS symbol sequence modulated by on-off keying (OOK) or frequency shift keying (FSK). The WUR may comprise a correlator for the enhanced WUS symbol sequence and a corresponding peak detector for detecting the enhanced WUS.

In some embodiments, the enhanced WUS is configured for more robust detection than one or more other WUS types (e.g., legacy WUSs, and/or WUS types with lower priority than the enhanced WUS). For example, more robust detection may comprise one or more of: higher detection probability, lower detection latency, and lower false alarm probability. Thereby, the WUR may be enabled to use an operation mode with even lower power consumption than its normal operation mode. For example, the enhanced WUS being configured for more robust detection may allow the WUR to operate at a reduced receiver operation performance (e.g., having a higher noise level), which may allow for even lower power consumption than the normal operation mode of the WUR.

In some embodiments, the enhanced WUS may be configured for robust detection by including error detection coding and/or error correction coding. In the WUR, corresponding error detection check and/or error correction may be implemented using any suitable means. For example, the WUR may comprise circuitry configured for error detection (e.g., running disparity checks) and/or error correction (e.g., running decoding for a forward error correcting code).

Transmitting the enhanced WUS may comprise using higher transmission power than for one or more other WUS types, and/or higher redundancy (e.g., more duplication bits, lower code rate) than for one or more other WUS types, and/or a modulation with larger minimum symbol distance (i.e., a modulation scheme which is more tolerant to noise and interference) than for one or more other WUS types; all of which renders the detection more robust.

Alternatively or additionally, transmitting the enhanced WUS may comprise using more frequency resources and/or more time resources than for one or more other WUS types. This allows the WUR to be less stringent regarding time/frequency where enhanced WUS monitoring is performed, and/or to monitor enhanced WUS less often than normal WUS monitoring. For example, the enhanced WUS may be transmitted more often than one or more other WUS types, and/or in more instances than one or more other WUS types.

The enhanced WUS is configured to trigger the communication device to leave sleep mode. For example, the enhanced WUS may be configured to trigger wake-up of a default transceiver of the communication device.

Before the sleep mode of the communication device (e.g., during a registration process of the communication device, and/or in preparation for sleep mode, and/or at any suitable time when the communication device is in connected mode), the method 600 may comprise receiving an enhanced WUS capacity report from the communication device, as illustrated by optional step 610. In some embodiments, reception of a do-not-disturb indication (before or during sleep mode) is considered as an implicit enhanced WUS capacity report.

The enhanced WUS capacity report may indicate whether the communication device is capable of enhanced WUS detection. In some embodiments, the enhanced WUS capacity report may also indicate particulars of the restricted WUS activity mode (e.g., when, how often, and at what frequencies the communication device will monitor enhanced WUS, and/or desired robustness parameters).

The transmission of the enhanced WUS in step 640 may be conditioned on reception of the enhanced WUS capacity report. For example, if no enhanced WUS capacity report has been received, it may be assumed that the communication device is not capable of enhanced WUS detection and/or restricted WUS activity mode operation, and the procedure exemplified by the method 600 is typically not executed at all.

In some embodiments, the enhanced WUS is comprised in a collection of WUS types with different wake-up priorities (e.g., corresponding to different acceptable wake-up latencies). Thus, there may be several WUS types with different priorities. Correspondingly, there may be several restricted WUS activity modes with different levels of restriction.

For example, there may be a low priority WUS (e.g., a legacy WUS), a medium priority WUS, and a high priority WUS. Both the medium priority WUS and the high priority WUS may be regarded as enhanced WUSs. Correspondingly, there may be a default WUS activity mode, a first restricted WUS activity mode, and a second restricted WUS activity mode. In the default WUS activity mode, the communication device may monitor the low priority WUS, the medium priority WUS, and the high priority WUS. In the first restricted WUS activity mode, the communication device may monitor the medium priority WUS and the high priority WUS. In the second restricted WUS activity mode, the communication device may monitor only the high priority WUS.

In some embodiments, different WUS priorities may relate to different latencies for wake-up. Thus, in one example related to different WUS priorities, different WUS activity modes may be associated with the expected reachability requirements of the data usage of the device. The expected reachability requirements of the data usage of the device may, for example, relate to one or more of: different use cases, different device types, different application types, different QoS levels, different radio bearer information of data traffic typically used by the device, and similar parameters which are indicative of the reachability requirement.

When there is a collection of WUS types with different wake-up priorities, several do-not-disturb/will-not-disturb indications may be used to indicate the applicable restricted WUS activity mode. Alternatively or additionally, the enhanced WUS capacity report may specify the applicable restricted WUS activity mode. Yet alternatively or additionally, the enhanced WUS capacity report may specify the number of wake-up priorities and/or their corresponding WUSs.

FIG. 7 illustrates an example method 700 according to some embodiments. The method 300 is for a communication device in sleep mode.

For example, the method 700 may be performed by one or more of: the UE 111, the UE 112, the UE 113, the AD 121, and the AD 122 of FIG. 1; while controlled by the BS 101 and/any of the relay nodes of FIG. 1.

Alternatively or additionally, the method 700 may be performed by a communication device while controlled by a node performing the method 600 of FIG. 6.

The method 700 may, for example, be performed by a communication device comprising a default transceiver and a wake-up receiver (WUR), wherein the default transceiver is configured to be inactive when the communication device is in sleep mode and the WUR is configured to be operative when the communication device is in sleep mode. The WUR may be implemented in any suitable way (e.g., as commonly implemented for WUS detection).

While the communication device is in sleep mode, as illustrated by 720 (compare with 620 of FIG. 6), the method 700 comprises establishing a restricted wake-up signal, WUS, activity mode of the communication device, as illustrated by step 730 (compare with step 630 of FIG. 6).

Establishing the restricted WUS activity mode of the communication device may comprise transmitting a do-not-disturb indication, as illustrated by optional sub-step 732 (compare with sub-step 632 of FIG. 6). For example, the do-not-disturb indication may be comprised in a DSM response, or in a DSM signaling configuration for the communication device.

Alternatively or additionally, establishing the restricted WUS activity mode of the communication device may comprise receiving a will-not-disturb indication, as illustrated by optional sub-step 734 (compare with sub-step 634 of FIG. 6).

It should be noted that the transmission of the do-not-disturb indication and/or the reception of the will-not-disturb indication may be performed before the communication device enters into sleep mode, according to some embodiments.

Other features and examples of the restricted WUS activity mode are derivable from the description in connection to FIG. 6.

The method also comprises triggering the communication device to leave sleep mode responsive to detection of an enhanced WUS, as illustrated by steps 750 and 760 (compare with step 640 of FIG. 6). In some embodiments, the communication device is triggered to leave sleep mode only responsive to detection of the enhanced WUS (or only responsive to detection of a WUS type with the same priority as, or higher priority than, the enhanced WUS).

Typically, the enhanced WUS is detected by a WUR of the communication device, and triggering the communication device to leave sleep mode comprised the WUR triggering activation (i.e., wake-up) of a default transceiver of the communication device.

Other features and examples of the enhanced WUS are derivable from the description in connection to FIG. 6.

In some embodiments, the method 700 comprises enhanced WUS monitoring (as illustrated by optional step 740). For example, step 740 may comprise monitoring only enhanced WUS (or only WUS types with the same priority as, or higher priority than, the enhanced WUS). Typically, step 740 may comprise enhanced WUS monitoring (only) during time periods and/or on frequencies where enhanced WUS is expected.

At the latest when a time period where enhanced WUS is expected has lapsed, the method 700 may proceed to step 750, where it is determined whether any enhanced WUS was detected.

When an enhanced WUS has been detected (Y-path out of step 750), the method 700 proceeds to step 760 where the communication device is triggered to leave sleep mode. When no enhanced WUS has been detected (N-path out of step 750), the method 700 may loop back to step 740 for continued enhanced WUS monitoring.

Before the sleep mode of the communication device (e.g., during a registration process of the communication device, and/or in preparation for sleep mode, and/or at any suitable time when the communication device is in connected mode), the method 700 may comprise transmitting an enhanced WUS capacity report, as illustrated by optional step 710 (compare with step 610 of FIG. 6). In some embodiments, transmission of a do-not-disturb indication (before or during sleep mode) is considered as an implicit enhanced WUS capacity report.

Other features and examples of the enhanced WUS capacity report are derivable from the description in connection to FIG. 6.

As already explained and exemplified in connection with FIG. 6, the enhanced WUS may be comprised in a collection of WUS types with different wake-up priorities. Thus, there may be several WUS types with different priorities, and several restricted WUS activity modes with different levels of restriction.

Other features and examples related to the collection of WUS types with different wake-up priorities are derivable from the description in connection to FIG. 6.

In some embodiments, the enhanced WUS capacity report (step 610 of FIG. 6 and step 710 of FIG. 7) may be conveyed together with the DSM signaling capacity report (step 205 of FIG. 2 and step 305 of FIG. 3).

Generally, the sleep mode of the communication device may also include modes where the communication device does not monitor paging during certain time periods (i.e., the communication device is not expected to be reachable by the network). For example, a communication device may be considered as being in sleep mode when operating in either of: extended discontinuous reception (eDRX), power save mode (PSM), and mobile initiated communication only (MICO) mode. According to some embodiments, a communication device may be configured to monitor enhanced WUS during such operation.

When a communication device is associated with the network via a relay node, the enhanced WUS may be used to differentiate between the relay node and the communication device for WUS/DSM response. For example, a communication device in sleep mode may delegate to a relay node to monitor (and react to) legacy WUS and/or DSM request, while the communication device may be configured to monitor and react to enhanced WUS. In some embodiments, do-not-disturb indications received by a relay node from a plurality of communication devices may be aggregated and passed on to the network. The network may (e.g., based on urgency) send an enhanced WUS directly to a communication device and/or via the relay node.

In some situations, the relay node may be configured to monitor legacy WUS and send an enhanced WUS to the communication device responsive to detection of a WUS for the communication device. In some situations, the relay node may be configured to monitor DSM request and send a DSM response on behalf of the communication device. In some situations, the relay node may be configured to monitor enhanced WUS and forward them to the communication device. Thus, according to some embodiments, a relay node may be configured to always forward an enhanced WUS to the communication device, while a legacy WUS may be served by the relay node or conveyed to the communication device as an enhanced WUS.

The enhanced WUS may be used to override a do-not-disturb indication transmitted by the communication device. Alternatively or additionally, the enhanced WUS may be used to reach a communication device during periods when it does not monitor paging. Yet alternatively or additionally, the enhanced WUS may be used to reach a communication device directly even if legacy WUS monitoring has been delegated to a relay node.

In the context of 3GPP, the wus capacity report may, for example, be provided via ue capability signaling.

Generally, the communication device may also provide a recommendation regarding when the enhanced WUS protocol should be used. In the context of 3GPP, such a recommendation may, for example, be provided via RRC signaling of UE assistance information.

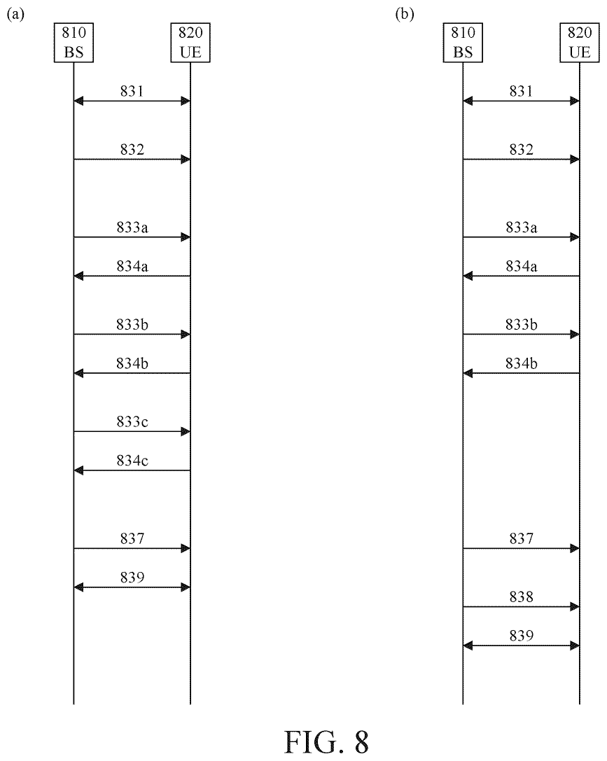

FIG. 8 illustrates two examples—(a) and (b)—of signaling between a radio access network and a communication device, for monitoring and/or controlling the communication device in sleep mode. The radio access network is represented by a base station (BS) 810, and the communication device is represented by a user equipment (UE) 820.

Referring to FIG. 1, the BS 810 may correspond to the BS 101 and the UE 820 may correspond to the UE 111, for example. Alternatively or additionally, the BS 810 may configured to perform the method 200 of FIG. 2 and/or the method 600 of FIG. 6, while the UE 820 may be configured to perform the method 300 of FIG. 3 and/or the method 700 of FIG. 7.

According to the example (a) of FIG. 8, the signaling starts by WUS configuration 831. The WUS configuration 831 comprises activation of a deep sleep monitoring (DSM) function. With the exception of the activation of the DSM function, the WUS configuration 831 may be in accordance with any suitable approach (e.g., according to known WUS configuration protocols).

Then, the UE 820 is caused to transfer to sleep mode (e.g., an idle mode). This is illustrated in FIG. 8 by signaling 832 (compare with 220 of FIG. 2, and 315 of FIG. 3).

While the UE 820 is in sleep mode, the BS 810 transmits DSM requests to the UE 820 as illustrated by 833a, 833b, 833c (compare with step 230 of FIG. 2). The UE 820 performs DSM request monitoring (compare with step 325 of FIG. 3). When a DSM request is detected (compare with steps 326, 330 of FIG. 3), the UE 820 transmits a DSM response as illustrated by 834a, 834b, 834c (compare with step 335 of FIG. 3). The BS 810 performs DSM response monitoring (compare with step 235 of FIG. 2), during which the DSM response is received by the BS 810 (compare with step 236 of FIG. 2).

The BS 810 can trigger the UE 820 to leave sleep mode by transmitting a WUS, as illustrated by 837. Signaling associated with leaving sleep mode is illustrated by 839. The WUS 837 and the signaling 839 associated with leaving sleep mode may be in accordance with any suitable approach (e.g., according to known WUS signaling and/or according to known signaling protocols for leaving sleep mode).

Other features and examples relating to the DSM function are derivable from the description in connection to FIGS. 2 and 3.

According to the example (b) of FIG. 8, the signaling starts by WUS configuration 831, including activation of the DSM function.

Then, the UE 820 is caused to transfer to sleep mode (e.g., an idle mode). This is illustrated in FIG. 8 by signaling 832 (compare with 220 of FIGS. 2, 315 of FIGS. 3, 620 of FIG. 6, and 720 of FIG. 7).

Similarly to the example (a) of FIG. 8, the BS 810 transmits DSM requests 833a, 833b to the UE 820 while the UE 820 is in sleep mode, and the UE 820 transmits corresponding DSM responses 834a, 834b.

A restricted WUS activity mode can be established, for example, by letting a DSM response 834b comprise a do-not-disturb indication (compare with steps 630, 632 of FIG. 2, and steps 730, 732 of FIG. 7).

When a restricted WUS activity mode is established, the BS 810 refrains from transmitting any further DSM requests (833c lacking from the example (a) of FIG. 8). Furthermore, when a restricted WUS activity mode is established, the UE 810 does not leave sleep mode in response to a default (“normal”) WUS 837 transmitted from the UE 820 (e.g., since the UE 820 does not perform default WUS monitoring, and/or since the UE 820 is configured to not leave sleep mode when a default WUS is detected during the restricted WUS activity mode).

During the restricted WUS activity mode, the BS 810 can trigger the UE 820 to leave sleep mode by transmitting an enhanced WUS, as illustrated by 838 (compare with step 640 of FIG. 6). When the enhanced WUS 838 is detected by the UE 820 (compare with step 750 of FIG. 7), the UE 820 is triggered to leave sleep mode (compare with step 760 of FIG. 7). Signaling associated with leaving sleep mode is illustrated by 839.

Other features and examples relating to the restricted WUS activity mode are derivable from the description in connection to FIGS. 6 and 7.

FIG. 9 illustrates two examples—(a) and (b)—of signaling according to some embodiments.

Example (a) illustrates example signaling between a user equipment (UE) 910, a base station (BS) 930, a reachability management function (RMF) 940, and an application server (AS) 950.

This specific example shows how a notification of unreachable UE may be triggered after two consecutively failed attempts to reach the UE.

The signaling starts with UE capability 970 being sent from the UE to the BS. Subsequently, the BS sends a DSM assistance request 971 to the UE, which the UE responds to with a DSM assistance response 972.

DSM information 973 is provided by the BS to the RMF. The RMF sends a DSM request 974 to the AS, which responds with a DSM configuration response 975. Then, the RMF provides a DSM parameter setting 986 to the BS.

Using the DSM parameter setting, the BS sends a first DSM request 978a to the UE and receives a corresponding DSM response 979a. Consequently, the BS can notify the RMF that the UE is reachable, as illustrated by 980.

Subsequently, the BS sends a second DSM request 978b to the UE and receives a corresponding DSM response 979b (i.e., the UE is still reachable).

When the BS sends a third DSM request 978c to the UE, no corresponding DSM response is received.

After sending a fourth DSM request 978d to the UE, without receiving any corresponding DSM response, the BS notifies the RMF that the UE is unreachable, as illustrated by 981. The unreachability notification is provided by the RMF to the AS, as illustrated by 982.

Example (b) illustrates example signaling for a relayed scenario; between a user equipment (UE) 910, a relay node (RN) 920, a base station (BS) 930, a reachability management function (RMF) 940, and an application server (AS) 950.

This specific example shows how a notification of unreachable UE may be triggered after two consecutively failed attempts to reach the UE.

The signaling starts with UE capability 970 being sent from the UE to the RN. Subsequently, the RN sends a DSM configuration request to the AS via the BS and the RMF, as illustrated by 974a, 974b, 974c.

A corresponding DSM configuration response is provided by the AS to the RN via the RMF and the BS, as illustrated by 975c, 975b, 975a. Then, the RN provides a DSM parameter setting 977 to the UE.

Using the DSM parameter setting, the RN sends a first DSM request 978a to the UE and receives a corresponding DSM response 979a. Consequently, the RN can notify the RMF via the BS that the UE is reachable, as illustrated by 980a, 980b.

Subsequently, the RN sends a second DSM request 978b to the UE and receives a corresponding DSM response 979b (i.e., the UE is still reachable).

When the RN sends a third DSM request 978c to the UE, no corresponding DSM response is received.

After sending a fourth DSM request 978d to the UE, without receiving any corresponding DSM response, the RN notifies the RMF via the BS that the UE is unreachable, as illustrated by 981a, 981b. The unreachability notification is provided by the RMF to the AS, as illustrated by 982.

FIG. 10 schematically illustrates an example transmitter 1000 for provision of a signal for transmission. The transmitter 1000 is suitable for operation with restricted power consumption.

For example, the transmitter 1000 may be comprisable (e.g., comprised) in a communication device, which further comprises a default transceiver configured for operation with power consumption which is higher than the restricted power consumption of the transmitter 1000. Alternatively or additionally, the transmitter 1000 may be comprisable in an integrated circuit (e.g., on an integrated circuit chip) which may possibly also comprise a wake-up receiver (WUR). Generally, an integrated circuit comprising the transmitter 1000 (and possibly a WUR) is typically configured for operation at a relatively low power consumption (e.g., lower than a power consumption of circuitry of a default transceiver).

In some embodiments, the transmitter 1000 is configured to be operative while the communication device, in which the transmitter 1000 is comprised, is in sleep mode (e.g., while a default transceiver of the communication device is inactive). Thus, the signal for transmission may comprise a signal to be transmitted when the communication device is in sleep mode.

Example signals that might be transmitted when the communication device is in the sleep mode (i.e., that might be provided and/or transmitted by the transmitter 1000) include radio link monitoring (RLM) reports, deep sleep monitoring (DSM) responses, responses to (or confirmations of) messages received by a WUR comprised in the same communication device as the transmitter, device status reports, configuration reports, and do-not-disturb indications. Alternatively or additionally, a signal provided and/or transmitted by the transmitter 1000 when the communication device is in the sleep mode may comprise small amounts of data (e.g., an amount of data which is smaller than a data amount threshold); such as sensor data.

Generally, a signal provided and/or transmitted by the transmitter 1000 may comprise any suitable information.

It should be noted that, even though the transmitter 1000 is described in the context of a communication device in sleep mode, wherein the communication device comprises a transceiver and a WUR, the transmitter 1000 is also suitable for other contexts. For example, the transmitter 1000 may be used as main/default/only transmitter for a low power device or an ultra-low power device (e.g., an IoT-device or other auxiliary device). Example low/ultra-low power devices include communication devices powered only by a non-changeable, or non-rechargeable, power source (e.g., a non-chargeable, or non-rechargeable, battery) and/or unpredictable power supply (e.g., energy harvesting, such as solar power).

The transmitter 1000 comprises a signal generation oscillator (SGO) 1010 configured to provide a signal 1004 for transmission. For example, the signal generation oscillator 1010 may be a voltage-controlled oscillator (VCO) and/or a radio frequency (RF) oscillator.

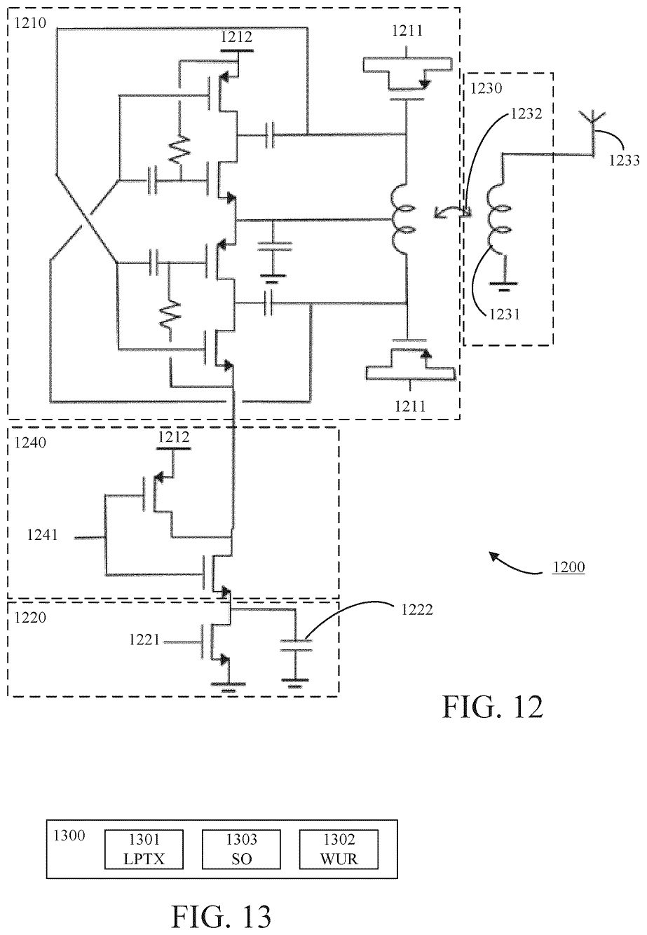

The signal generation oscillator 1010 may be operatively connectable (e.g., connected) to an antenna (ANT) 1090 via tapping circuitry (TC) 1080. Generally, the tapping circuitry 1080 may be any suitable circuitry for transferring at least part of the signal provided by the signal generation oscillator 1010 to the antenna 1090. An example tapping circuitry will be described in connection with FIG. 12. The tapping circuitry 1080 and/or the antenna 1090 may, or may not, be comprised in the transmitter 1000.

The transmitter 1000 also comprises a phase-locked loop (PLL) 1020. The PLL 1020 is configured to calibrate an oscillator frequency of the signal generation oscillator 1010 in relation to a reference frequency 1001, by providing a first control signal 1002 to the signal generation oscillator 1010.

The reference frequency 1001 may be provided by a reference oscillator (RO) 1040. For example, the reference oscillator 1040 may be a crystal oscillator (e.g., a low power crystal oscillator) or a Micro-Electro-Mechanical-System (MEMS) oscillator. In some embodiments, the reference frequency 1001 may be provided by letting the output of the reference oscillator 1040 be followed by a frequency multiplier or by a reference frequency PLL (which is different from the PLL 1020) to increase the frequency provided by the reference oscillator.

In any ace, the reference oscillator 1040 may, or may not, be comprised in the transmitter 1000. In some embodiments, the reference oscillator is shared with a WUR comprised in the same integrated circuit as the transmitter 1000.

The PLL 1020 may be implemented in any suitable way. For example, the PLL 1020 may be an analog PLL.

Typically, the PLL 1020 has a feedback path 1005 from the signal generation oscillator 1010. In some embodiments, the feedback path 1005 comprises a frequency divider configured to specify a ratio between the reference frequency 1001 and the oscillator frequency.

Also typically, the PLL may comprise an error detector and a loop filter (e.g., a low-pass filter, LPF). The error detector typically detects phase errors between its input signals, and often also detects frequency errors, which reduces the time required for the PLL to acquire lock. The error detector may be configured to receive the reference frequency 1001 and a feedback signal provided by the feedback path 1005, and to provide a corresponding phase difference indicator. The loop filter may be configured to provide the first control signal 1002 based on the phase difference indicator. The PLL may also comprise one or more controlled current sources (e.g., a charge pump) configured to provide a charging current to the loop filter based on the phase difference indicator, and the loop filter may be configured to provide the first control signal 1002 responsive to the charging, in the form of a control voltage.

The transmitter 1000 also comprises holding circuitry (HC) 1030 configured to maintain a digital representation of the first control signal 1002 provided by the PLL 1020, for provision of a second control signal 1003 to the signal generation oscillator 1010 when the PLL 1020 is inactive. For example, the holding circuitry 1030 may comprise an analog to digital converter (ADC), such as a successive approximation register (SAR) ADC, a pipeline ADC, a delta-sigma ADC, a flash ADC, etc.

The transmitter 1000 may further comprise a digital-to-analog converter (DAC) 1050 configured to provide the second control signal 1003 to the signal generation oscillator 1010 based on the digital representation of the first control signal 1002 maintained by the holding circuitry 1030. For example, the DAC 1050 may be configured to provide an analog version of the digital representation maintained by the holding circuitry 1030 as the second control signal 1003.

Generally, the second control signal 1003 may be seen as an approximation of the first control signal 1002. For example, the digital representation of the first control signal 1002 maintained by the holding circuitry 1030 may be seen as an approximation of the first control signal 1002, and the second control signal 1003 may be seen as an approximation of the digital representation of the first control signal 1002 maintained by the holding circuitry 1030.

The transmitter 1000 may further comprise switching circuitry (SC) 1060 configured to provide the first control signal 1002 to the signal generation oscillator 1010 when the PLL 1020 is active, and to provide the second control signal 1003 to the signal generation oscillator 1010 when the PLL 1020 is inactive.

A controller (CNTR; e.g., controlling circuitry or a control module) 1070 may be configured to control one or more parts of the transmitter 1000. To this end, the controller 1070 may be operatively connected (or connectable) to one or more of the other parts of the transmitter 1000. The controller 1070 may, or may not, be comprised in the transmitter 1000.

The controller 1070 may be configured to control the transmitter 1000 in at least a calibration phase, a settling phase, and a maintenance phase. In some embodiments, the controller 1070 is also configured to control the transmitter 1000 in an inactive phase.

During the calibration phase, the controller 1070 may be configured to cause the PLL 1020 to be active. The calibration phase is typically applied when frequency calibration is deemed suitable (e.g., when some time has passed since the previous calibration phase and/or following an inactive phase of the transmitter 1000).

The controller 1070 may also be configured to cause the switching circuitry 1060 to provide the first control signal 1002 to the signal generation oscillator 1010 during the calibration phase.

Typically, the controller 1070 is configured to cause the holding circuitry 1030 to be inactive during the calibration phase.

During the settling phase, the controller 1070 may be configured to cause the PLL 1020 to be at least partially inactive, and the holding circuitry 1030 to be active. The settling phase is typically applied directly following the calibration phase, and is configured to enable the digital representation of the first control signal 1002 to be settled in the holding circuitry 1030 (i.e., the digital representation of the first control signal 1002 is attained by the holding circuitry 1030 during the settling phase).

The controller 1070 may also be configured to cause the switching circuitry 1060 to provide the first control signal 1002 to the signal generation oscillator 1010 during the settling phase.

During the maintenance phase, the controller 1070 may be configured to cause the PLL 1020 to be inactive and the holding circuitry 1030 to be active. Inactivity of the PLL 1020 typically entails substantial power savings. The maintenance phase is typically applied following the settling phase (directly and/or after an inactive time of the transmitter 1000).

The controller 1070 may also be configured to cause the switching circuitry 1060 to provide the second control signal 1003 to the signal generation oscillator 1010 during the maintenance phase.

During the inactive phase of the transmitter 1000, the controller 1070 may be configured to cause the PLL 1020 to be inactive, and the signal generation oscillator 1010 to be turned off. The inactive phase of the transmitter 1000 is typically applied whenever no signal for transmission needs to be provided by the signal generation oscillator 1010 (and no PLL calibration or holding circuitry settling is needed). Thus, the state of the switching circuitry 1060 is typically unimportant during the inactive phase of the transmitter 1000.

For example, the inactive phase of the transmitter 1000 may comprise a complete, or partial, power down of the transmitter 1000.

When the inactive phase of the transmitter 1000 comprises a complete power down of the transmitter 1000, all parts of the transmitter 1000 are typically inactive.

When the inactive phase of the transmitter 1000 comprises a partial power down of the transmitter 1000, the controller 1070 may be configured to cause the holding circuitry 1030 to be active during the inactive phase of the transmitter 1000. This has the benefit that the calibration and settling phases may be omitted for an upcoming transmission occasion; at least if the inactive phase of the transmitter 1000 was sufficiently short (e.g., shorter than a threshold value). In some embodiments, one or more sensor (e.g., a temperature sensor and/or a voltage sensor) may be used to determine whether or not the calibration and settling phases may be omitted for an upcoming transmission occasion. For example, if sensor readouts are substantially the same (e.g., with a variation less than a threshold value) as they were at previous calibration and settling phases, and/or as they were at a previous transmission occasion (e.g., at a previous transmission occasion directly preceded by calibration and settling), the calibration and settling phases may be omitted for an upcoming transmission occasion.

The transmitter 1000 may be configured to modulate the signal for transmission using on-off keying, OOK, or using frequency shift keying, FSK.

One example implementation of OOK comprises the transmitter 1000 being configured to operate the signal generation oscillator 1010 in an active mode for provision of an on-symbol of the OOK and in an inactive mode for provision of an off-symbol of the OOK. For example, the controller 1070 may be configured to cause the operation of the signal generation oscillator 1010 in the active and inactive modes.

One example implementation of OOK comprises the transmitter 1000 being configured to operate the tapping circuitry 1080 between a signal transfer mode for provision of an on-symbol of the OOK and a signal blocking mode for provision of an off-symbol of the OOK. For example, the controller 1070 may be configured to cause the operation of the tapping circuitry 1080 in the transfer and blocking modes.

One example implementation of FSK comprises the transmitter 1000 being configured to dynamically adjust (for each FSK symbol) the digital representation of the first control signal 1002 provided by the holding circuitry 1030 to provide the second control signal 1003 as having a value that corresponds to the frequency for the FSK symbol. For example, the controller 1070 may be configured to dynamically adjust an output of the holding circuitry 1030 to a value that corresponds to the frequency for the FSK symbol, before provision as an input to the DAC 1050.

One example implementation of FSK comprises the transmitter 1000 being configured to dynamically adjust (for each FSK symbol) a bias voltage of a varactor comprised in the signal generation oscillator 1010 to provide a shift of the frequency provided by the signal generation oscillator 1010, wherein the shift corresponds to the frequency shift for the FSK symbol. For example, the controller 1070 may be configured to dynamically adjust the bias voltage of the varactor to a value that provides a frequency shift that corresponds to the frequency shift for the FSK symbol.

FIG. 11 schematically illustrates an example transmitter 1100 for provision of a signal for transmission. The transmitter 1100 is suitable for operation with restricted power consumption. In some embodiments, the transmitter 1100 may be seen as an exemplification of the transmitter 1000 of FIG. 10.

The transmitter 1100 comprises a signal generation oscillator (SGO) 1106 configured to provide a signal for transmission (compare with the signal generation oscillator 1010 of FIG. 10).

The signal generation oscillator 1106 is operatively connectable (e.g., connected) to an antenna 1131 via tapping circuitry (TAP) 1130 (compare with the antenna 1090 and the tapping circuitry 1080 of FIG. 10). An example tapping circuitry will be described in connection with FIG. 12.

The transmitter 1100 also comprises an analog PLL (compare with the PLL 1020 of FIG. 10). The PLL is configured to calibrate an oscillator frequency of the signal generation oscillator 1106 in relation to a reference frequency (REF) 1101 (compare with the reference frequency 1001 of FIG. 10), by providing a first control signal 1191 (compare with the first control signal 1002 of FIG. 10) to the signal generation oscillator 1106.

The PLL has a feedback path 1190 from the signal generation oscillator 1106 (compare with the feedback path 1005 of FIG. 10), which comprises a frequency divider (DIV) 1110 configured to specify a ratio between the reference frequency 1101 and the oscillator frequency of the signal generation oscillator 1106.

The PLL comprises an error detector in the form of a phase/frequency detector (PFD) 1102, one or more controlled current sources in the form of a charge pump (CP) 1103, and a loop filter in the form of a low-pass filter (LPF) 1104. The phase/frequency detector 1102 is configured to receive the reference frequency 1101 and a feedback signal provided by the feedback path 1190, and to provide a corresponding phase difference indicator. The charge pump 1103 is configured to provide charging based on the phase difference indicator, and the low-pass filter 1104 is configured to provide the first control signal 1191 responsive to the charging, in the form of a control voltage.

Using an analog PLL may be beneficial due to its simplicity. However, due to leakage in the charge pump 1103 (even when the charge pump is turned off), the first control signal 1191 may change over time so that the frequency of the signal generation oscillator 1106 drifts when the PLL is inactivated (e.g., during transmission and/or between transmission occasions). Alternatively or additionally, the frequency of the signal generation oscillator 1106 may drift when the signal generation oscillator 1106 is turned on and off for OOK modulation, because this may lead to that charge is pumped into capacitors of the LPF 1104.

The frequency drift may be mitigated by quantizing the output of the LPF 1104 (i.e., the first control signal 1191), storing a digital representation of the first control signal 1191, and using the digital representation to control the signal generation oscillator 1106.

To this end, the transmitter 1100 also comprises a successive approximation register (SAR) 1107 and a digital-to-analog converter (DAC) 1108 (compare with the holding circuitry 1030 and the DAC 1050 of FIG. 10). The SAR 1107 is configured to maintain a digital representation of the first control signal 1191, and the DAC 1108 is configured to—when the PLL is inactive—provide a second control signal 1192 (compare with the second control signal 1003 of FIG. 10) to the signal generation oscillator 1106 based on the digital representation maintained by the SAR 1107.

The transmitter 1100 further comprises a comparator (CMP; e.g., comparing circuitry) 1109. The comparator 1109 is configured to provide an input to the SAR 1107 based on a difference between the first control signal 1191 and the second control signal 1192.

The transmitter 1100 further comprises a switch 1105 (compare with the switching circuitry 1060 of FIG. 10). The switch 1105 is configured to provide the first control signal 1191 to the signal generation oscillator 1106 when the PLL is active, and to provide the second control signal 1192 to the signal generation oscillator 1106 when the PLL is inactive.

The transmitter 1100 also comprises controller (CNTR; e.g., controlling circuitry or a control module; compare with the controller 1070 of FIG. 10) 1120 configured to control the transmitter 1100.

The controller 1120 is configured to control the transmitter 1100 in a calibration phase, a settling phase, a maintenance phase, and an inactive phase.

During the calibration phase, the controller 1120 causes the PLL to be active; and the switch 1105 to provide the first control signal 1191 to the signal generation oscillator 1106. Typically, the controller 1120 causes the SAR 1107 and the comparator 1109 to be inactive during the calibration phase.

During the settling phase, the controller 1120 causes at least part of the PLL to be active. For example, the controller 1120 may turn off the PFD 1102, the CP 1103, and the DIV 1110 in the settling phase. The CP 1103 may be turned off by setting its output current to zero (i.e., stopping it from charging the LPF 1104), while keeping its supply voltage on. Then, the voltage of the (passive) LPF 1104 can be maintained by a capacitance of the LPF 1104, thereby providing a sample-and-hold function for maintenance of the digital representation in the SAR 1107. Furthermore, the controller 1120 causes the SAR 1107 and the comparator 1109 to be active during the settling phase; and the switch 1105 to provide the first control signal 1191 to the signal generation oscillator 1106. During the settling phase, the digital representation of the first control signal 1191 is attained in the SAR 1107.

One approach for attaining the digital representation of the first control signal 1191 in the SAR 1107 can be exemplified as follows (using an example where the SAR 1107 implements an 8-bit digital representation).

The controller 1120 starts with asserting the most significant bit (MSB) of the SAR 1107. The output signal of the DAC 1108 (i.e., the second control signal 1192) then corresponds to a 10000000 input signal, creating a corresponding hypothesized analog value for the second control signal 1192. The comparator 1109 checks whether this hypothesized analog value of the second control signal 1192 is higher or lower than the analog value of the first control signal 1191 (the digital representation of which should be settled in the SAR 1107). When the hypothesized analog value of the second control signal 1192 is higher than the analog value of the first control signal 1191 the MSB is set to “0” in the SAR 1107, and when the hypothesized analog value of the second control signal 1192 is lower than the analog value of the first control signal 1191 the MSB is set to “1” in the SAR 1107.

The controller 1120 continues with asserting the next bit (in order of significance) of the SAR 1107. The output signal of the DAC 1108 (i.e., the second control signal 1192) then corresponds to an x1000000 input signal, where “x” represents the already settled value for the MSB of the SAR 1107, creating a corresponding (new) hypothesized analog value for the second control signal 1192. The comparator 1109 checks whether this hypothesized analog value of the second control signal 1192 is higher or lower than the analog value of the first control signal 1191 (the digital representation of which should be settled in the SAR 1107). When the hypothesized analog value of the second control signal 1192 is higher than the analog value of the first control signal 1191 the bit under consideration is set to “0” in the SAR 1107, and when the hypothesized analog value of the second control signal 1192 is lower than the analog value of the first control signal 1191 the bit under consideration is set to “1” in the SAR 1107.

This process is performed for each bit of the SAR 1107, in order of significance. The result is that the SAR 1107 settles at a digital representation that corresponds to an analog value of the second control signal 1192, which is as close as possible to the analog value of the first control signal 1191 (i.e., smaller than the analog value of the least significant bit, LSB, of the DAC 1108 which is settled by the SAR 1107).

The control of the SAR operation can alternatively be implemented locally (e.g., as a local SAR controller in close vicinity to the SAR register), in which case the controller 1120 may send a start signal to the local SAR controller at the beginning of the settling phase, and the SAR controller executes the assertion.

It should be noted that the DAC 1108 may use binary weighting, or any other suitable weighting. Typically, there should be a reduction of the analog weights of the DAC bits as the process precedes from settling one bit in the SAR to settling the next bit in the SAR; but the ratio between adjacent bit weights can be less than two, where a ratio of two between adjacent bit weights corresponds to binary weighting. The nominal weight between adjacent bits should typically be in the interval between one and two, where one corresponds to unary weighting and two to binary weighting. Alternatively or additionally, the ratio between adjacent bit weights may differ between different pairs of adjacent bits of the DAC. For example, the most significant bits may have a different weight ratio between adjacent bits than the least significant bits.

Furthermore, it should be noted that the number of bits of the SAR 1107 and the range and resolution of the DAC 1108 may have any suitable values. For example, suitable values may be determined as a trade-off between performance (e.g., high resolution and/or large range) and low power consumption.

During the maintenance phase, the controller 1120 causes the PLL and the comparator 1109 to be inactive, the SAR 1107 and the DAC 1108 to be active; and the switch 1105 to provide the second control signal 1192 to the signal generation oscillator 1106.

Using the second control signal 1192 to the signal generation oscillator 1106, there is no risk that the frequency of the signal generation oscillator 1106 is affected by capacitor discharge in the LPF 1104 due to leakage currents. Furthermore, the digital representation can be re-used without activating the PLL for every transmission occasion (e.g., when temperature and voltage have not changed since previous calibration and settling phases, and/or since a previous transmission occasion).

Inactivation of the PLL may comprise altered operation of one or more of: the PFD 1102, the CP 1103, the LPF 1104, and the DIV 1110. For example, the controller 1120 may turn off the PFD 1102, the CP 1103, the LPF 1104, and the DIV 1110 in the maintenance phase.

During the inactive phase of the transmitter 1100, the controller 1120 may be configured to cause the PLL to be completely inactive, and the signal generation oscillator 1106 to be turned off. For example, the controller 1120 may turn off the voltage supply for the PFD 1102, the CP 1103, the LPF 1104, and the DIV 1110 in the inactive phase. Typically, the controller 1120 is also configured to cause the tapping circuitry 1130, the comparator 1109, the DAC 1108, and the switch 1105 to be completely inactive (e.g., by turning of their supply voltage). The SAR 1107 may be caused to be active or inactive during the inactive phase of the transmitter 1100, as elaborated on in connection with FIG. 10.

Other features and examples relating to the operation of the transmitter 1100 are also derivable from the description in connection to FIG. 10.

FIG. 12 illustrates example oscillating and tapping circuitry 1200 according to some embodiments. For example, the signal generation oscillator 1010 and the tapping circuitry 1080 of FIG. 10, and/or the signal generation oscillator 1106 and the tapping circuitry 1130 of FIG. 11 may be implemented using the oscillation and tapping circuitry 1200.

The oscillation and tapping circuitry 1200 comprises four portions 1210, 1220, 1230, 1240. A supply voltage Vad is provided at 1212, a control/tune voltage Ventr is provided at 1211, and a bias voltage VB is provided at 1221. For example, the control/tune voltage Ventr 1211 may correspond to the first/second control signal provided to the signal generation oscillator 1010, 1106 of FIGS. 10 and 11. The bias voltage 1221 controls conduction of the transistor in 1220 (i.e., controls the bias current for the oscillator).

Generally, the signal generation oscillator should preferably consume little power. Also, the signal generation oscillator should preferably start up quickly to support OOK. The oscillation and tapping circuitry 1200 may provide either or both of these characteristics.

A problem with ultra-low power oscillators is that they often use very low supply voltage (e.g., lower than the supply voltage of other parts of a device in which the oscillator is comprised, and/or lower than a battery voltage). Thereby, the system efficiency (including power management) may be reduced, and/or the power overhead of bias current sources may be increased.

The article “A 0.55 mW SAW-Less Receiver Front-End for Bluetooth Low Energy Applications” by Bryant and Sjöland, IEEE Journal of Emerging and Selected Topics in Circuits and Systems, Vol. 4, No. 3, pp. 262-272, September 2014 presents a very low power inductor/capacitor (LC) oscillator implemented in 65nm complementary metal-oxide-semiconductor (CMOS) and configured to operate at 5 GHz with a comparatively high supply voltage of 0.85V and less than 100 μW power consumption (see, e.g., FIG. 8 of the article). The oscillation and tapping circuitry 1200 is inspired by the oscillator of the above-mentioned article, but with additional features to support fast OOK (portion 1240) and coupling of the antenna to the oscillator (portion 1230). The coupling with the antenna provides a predominantly differential mode load. Thus, the architecture and function of portions 1210 and 1220 of the oscillation and tapping circuitry 1200 may be understood based on the above-mentioned article, and will not be elaborated on further herein.

The portion 1230 comprises a secondary winding 1231, which—together with a primary winding of the portion 1210—provides a transforming function as illustrated by 1232. Thereby, the secondary winding taps off power from the resonator of the oscillator to the antenna 1233 (compare with the antennas 1090, 1131 of FIGS. 10 and 11).

Thus, compared to the above-mentioned article, a secondary winding 1231 is added in association with the inductor of the resonator (the primary winding). This provides a predominantly differential mode load for the oscillator. The turns ratio and coupling factor of the transformer can be chosen so that a suitable amount of power is tapped off (i.e., a suitable load resistance is presented to the resonator through transformation). If too much power is tapped off, the resonator quality factor will drop significantly, and the power consumption must be increased significantly to be able to sustain oscillation. If too little power is tapped off, efficiency and output power will be impaired. A reasonable trade-off may be to tap off an output power of about 1/10 of the oscillator power consumption; enabling low power consumption and a transmitter efficiency of almost 10%.

In addition to serving as an impedance transformer with suitable coupling factor and turn ratio, the transformer can also serve as a balun and a level shifter, which may be beneficial when the antenna signal is single-ended and biased at ground potential.

The portion 1240 provides an implementation for operating the oscillation and tapping circuitry 1200 between an ON mode for provision of an OOK on-symbol and an OFF mode for provision of an OOK off-symbol. By varying the ON/OFF modulation signal 1241 between a high voltage (ON) and a low voltage (OFF), the portion 1240 may turn the oscillator portion 1210 ON and OFF. The signal tapped off to the antenna through portion 1230 can then be OOK modulated. The capacitance 1222 of the portion 1220 enables fast switching from an off-symbol to an on-symbol. This is because the charging of the capacitance 1222 will then momentarily increase the bias current, thereby increasing the oscillator startup loop-gain, and making the oscillator start faster. Fast switching from an on-symbol to an off-symbol is enabled by the PMOS transistor of portion 1240, since that PMOS transistor acts to minimize the voltage across the oscillator core 1210 in the OFF mode as described below.

The transistors of the portion 1240 (one N-channel metal-oxide-semiconductor, NMOS, transistor and one P-channel metal-oxide-semiconductor, PMOS, transistor) have their gate terminals connected to the ON/OFF modulation signal 1241.

When the ON/OFF modulation signal 1241 is high, the NMOS transistor is on and the PMOS transistor is off, and the oscillator core 1210 receives bias current from 1220 through the conducting NMOS transistor (i.e., the oscillator is ON).

When the ON/OFF modulation signal 1241 is low, the NMOS transistor is off and the PMOS transistor is on, and the oscillator core 1210 does not receive any bias current since the NMOS transistor does not conduct (i.e., the oscillator is OFF). Furthermore, the PMOS transistor pulls its drain voltage close to the supply voltage, ensuring very low voltage across the oscillator core 1210.

The capacitor 1222 at the bias transistor of the portion 1220 will be discharged (by the bias transistor) when the oscillator is OFF. When the oscillator turned ON, the oscillator core will first receive nearly the full supply voltage, until the capacitor has been charged, which speeds up the start-up of the oscillator. The start-up may be further speeded up by injection of differential mode signal current into the inductor (primary winding), since new bias voltages are established in the circuit when it is turned on, and the capacitors connected to the inductor terminals are charged by different amounts due to the voltage stacked nature of the circuit where different-otherwise equal-parts operate at different bias voltage.

FIG. 13 schematically illustrates an example integrated circuit (e.g., an integrated circuit chip) 1300 according to some embodiments. The integrated circuit 1300 comprises a low-power transmitter (LPTX) 1301, a wake-up receiver (WUR) 1302, and a shared oscillator (SO) 1303. It should be noted that there may, alternatively, be dedicated oscillators 1303 for each of the LPTX 1301 and the WUR 1302. Furthermore, it should be noted that-according to some embodiments-the shared oscillator (or the dedicated oscillators) 1303 may be provided external to the integrated circuit 1300 (e.g., on a separate integrated circuit chip).

The LPTX 1301 may, for example, comprise any of the transmitters 1000, 1100 of FIGS. 10 and 11. The oscillator 1303 may, for example, be the reference oscillator 1040 of FIG. 10. Alternatively or additionally, the oscillator 1303 may be configured to provide the reference frequency 1001, 1101 of FIGS. 10 and 11.

The integrated circuit 1300 may be particularly suitable for low power reception/detection and transmission. For example, it may be suitable for use in a communication device which also comprises a default transceiver, wherein the integrated circuit 1300 may be configured to detect one or more signal (e.g., WUS, enhanced WUS, DSM request, etc.) and/or transmit one or more signal (e.g., DSM response, do-not-disturb indication, etc.) while the communication device is in sleep mode.

In some embodiments, the integrated circuit 1300 is based on an ultra-low power micro-controller.

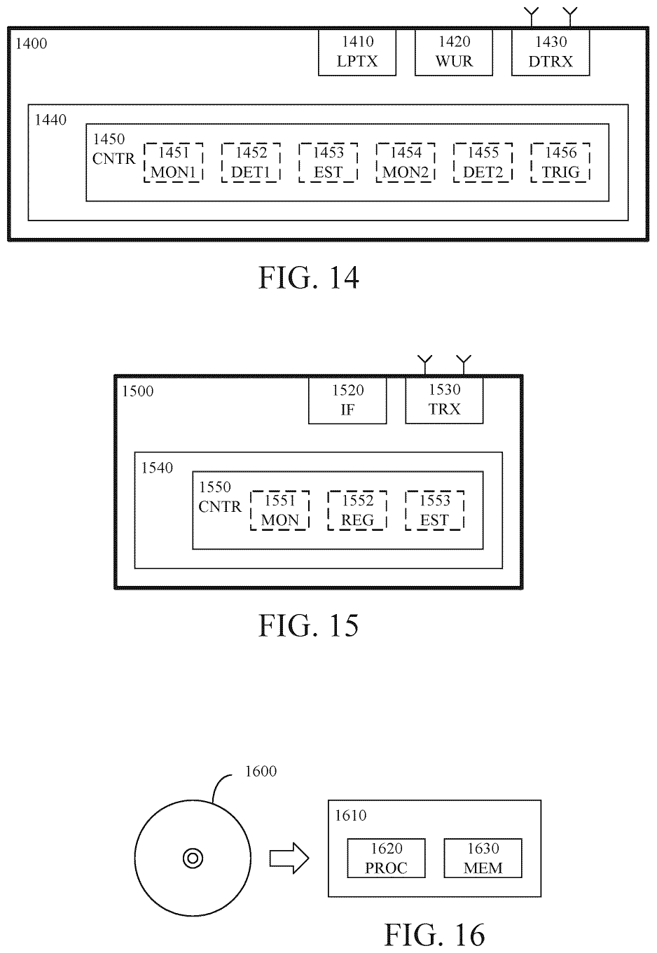

As exemplified in connection with FIGS. 10-13, and as will be further exemplified in connection with FIG. 14, a communication device may be equipped with a wake-up receiver (WUR) as well as a low power transmitter.

The wake-up receiver may be configured to receive/detect WUSs (e.g., WUSs of different priorities; including enhanced WUSs), and possibly also other WUS-like signals (e.g., DSM requests). Each type of signal configured to be received/detected by the WUR may be represented by a respective symbol sequence. Typically, the reception/detection comprises distinguishing which sequence is received/detected among a set of possible sequences, so that it can be determined which type of signal is received/detected.

When a DSM request is detected, the low power transmitter may be activated to transmit the DSM response and/or a do-not-disturb indication.

Some implementations of the low power transmitter use on-off keying modulation, which may be obtained by turning the signal generation oscillator on and off. A resonator of the signal generation oscillator may be coupled to an antenna via tapping circuitry.

To limit the frequency uncertainty of the signal generation oscillator (thereby enabling use of a more narrow receive filter for the signal transmitted by the low power transmitter; which typically improves sensitivity), the signal generation oscillator may be calibrated to a reference frequency using a PLL (e.g., when a transmission is about to start). The reference frequency may, for example, be generated by a low power crystal oscillator that can be shared between the low power transmitter and the WUR. When the PLL has locked, the control voltage of the signal generation oscillator may be kept fixed by using a successive approximation register (SAR) and a digital-to-analog converter (DAC). Then, the PLL may be turned off and the signal generation oscillator may be operated as free-running.

Fixing the control voltage of the signal generation oscillator by using the SAR and DAC, has the benefit that leakage currents, and/or potential pumping of charge, in the PLL loop filter (which may occur when turning the signal generation oscillator on and off) can be avoided, or at least mitigated. Furthermore, the frequency drift during transmission will typically be kept at a low level, and a relatively narrow filter can be used for reception of the transmitted signal, which typically reduces any impact of noise and interference.

Typically, it may be beneficial to optimize the PLL for fast frequency locking (i.e., having a high bandwidth), as well as ensuring PLL robustness for the reference frequency. A typical rule of thumb that may be applied comprises use of a bandwidth of up to 1/10 of the reference frequency. If the reference frequency is 10 MHz or higher (which is compatible with low power consumption), the PLL can be able to lock in a timescale of microseconds. The signal generation oscillator may, for example, operate around 2 GHz and have a 10% tuning range (i.e., a 200 MHz frequency range). If the resolution should be 2 MHz, a quantization with at least 100 steps is required (which corresponds to 7 bits; 128 steps), which may be achievable in a low power design.

In some embodiments, the low power transmitter enables deep sleep radio link monitoring. A communication device can respond to a DSM request while consuming very little power. Thereby, the network can receive a confirmation that a radio link is functional (e.g., perform a periodic radio link monitoring) without waking up the communication device from the sleep mode.

In some embodiments, the low power transmitter enables transmission of very small amounts of data (e.g., sensor readouts) while the communication device is in sleep mode.

In some embodiments, the low power transmitter can operate with accurate frequency of transmission, which may entail less impact of noise and interference when the transmitted signal is received.

In some embodiments, the low power transmitter can operate with very low power consumption. The power consumption is typically dominated by the signal generation oscillator, which may be modulated to be off approximately half of the transmission time (assuming OOK modulation is used).

In some embodiments, the low power transmitter uses an internal arrangement with a SAR and a DAC to eliminate/mitigate oscillator control voltage drift. This may entail a compact low power circuit with high frequency stability.

In some embodiments, the low power transmitter uses an effective oscillator structure for OOK (see, e.g., FIG. 12).

In some embodiments, the low power transmitter uses a transformer coupling from the oscillator resonator to feed the antenna (see, e.g., FIG. 12). This entails no significant circuit area overhead. Furthermore, the power may be tapped symmetrically from a differential oscillator.

FIG. 14 schematically illustrates an example apparatus 1440 for a communication device, wherein the communication device is configured for two or more modes; including a sleep mode and a non-sleep mode.

For example, the apparatus 1440 may be comprisable (e.g., comprised) in a communication device 1400 (e.g., a UE, or an auxiliary device such as an IoT-device—compare with 111, 121, 122, 113 of FIG. 1). Alternatively or additionally, the apparatus 1440 may be configured to cause execution of (e.g., execute) one or more method steps as described in connection with FIG. 3 and/or FIG. 7.

In some embodiments, the apparatus 1440 comprises, or is otherwise associated with (e.g., connectable, or connected, to), a default transceiver (DTRX; e.g., transceiving circuitry or a transceiver module) 1430. The default transceiver 1430 may be configured to be inactive when the communication device is in sleep mode. The default transceiver 1430 may be any suitable transceiver for wireless communication.

Alternatively or additionally, the apparatus 1440 may comprise, or be otherwise associated with (e.g., connectable, or connected, to), a wake-up receiver (WUR; e.g., wake-up receiving circuitry or a wake-up reception module) 1420. The WUR 1420 may be configured to be operative when the communication device is in sleep mode. The WUR 1420 may be any suitable WUR (e.g., comprising correlator and peak detector for detection of one or more pre-determined sequences).

Yet alternatively or additionally, the apparatus 1440 may comprise, or be otherwise associated with (e.g., connectable, or connected, to), a low power transmitter (LPTX; e.g., transmitting circuitry or a transmission module) 1410. The low power transmitter 1410 may be configured for operation with restricted power consumption, and to be operative when the communication device is in sleep mode. The low power transmitter 1410 may be any suitable transmitter (e.g., as described in connection with FIGS. 10 and 11).

For example, the default transceiver 1430, the WUR 1420, and the low power transmitter 1410 may be comprised in the communication device 1400, as illustrated by FIG. 14.

The apparatus 1440 comprises a controller (CNTR; e.g., controlling circuitry of a control module) 1450.

In some embodiments, the controller 1450 is configured to cause detection of a deep sleep monitoring (DSM) request while remaining in sleep mode (compare with step 326 of FIG. 3).

To this end, the controller 1450 may comprise, or be otherwise associated with (e.g., connectable, or connected, to), a detector (DET1; e.g., detecting circuitry or a detection module) 1452. The detector 1452 may be configured to detect the DSM request. In some embodiments, the detector 1452 is comprised in the WUR 1420.

The controller 1450 may be configured to cause DSM request monitoring (compare with step 325 of FIG. 3) to enable detection of the DSM request.

To this end, the controller 1450 may comprise, or be otherwise associated with (e.g., connectable, or connected, to), a monitor (MON1; e.g., monitoring circuitry or a monitor module) 1451. The monitor 1451 may be configured to monitor DSM occasion(s) where the DSM request is expected.

Responsive to detection of a DSM request, the controller 1450 may be configured to cause transmission of a DSM response while the communication device 1400 remains in sleep mode (compare with step 335 of FIG. 3). For example, the controller 1450 may be configured to cause the low power transmitter 1410 to transmit the DSM response.

In some embodiments, the controller 1450 is configured to cause establishment of a restricted WUS activity mode of the communication device 1400 (compare with step 730 of FIG. 7).

To this end, the controller 1450 may comprise, or be otherwise associated with (e.g., connectable, or connected, to), an establisher (EST; e.g., establishing circuitry or an establishment module) 1453. The establisher 1453 may be configured to establish the restricted WUS activity mode.

Establishment of the restricted WUS activity mode may comprise transmission of a do-not-disturb indication (compare with step 732 of FIG. 7) or reception of a will-not-disturb indication (compare with step 734 of FIG. 7). For example, the controller 1450 may be configured to cause the low power transmitter 1410 to transmit a do-not-disturb indication (e.g., comprised in a DSM response) while the communication device 1400 is in sleep mode. Alternatively or additionally, the controller 1450 may be configured to cause the WUR 1420 to detect a will-not-disturb indication (e.g., comprised in a DSM request) while the communication device 1400 is in sleep mode. Yet alternatively or additionally, the controller 1450 may be configured to cause the default transceiver 1430 to transmit a do-not disturb indication and/or receive a will-not-disturb indication while the communication device 1400 is in non-sleep mode.

While the communication device 1400 is in restricted WUS activity mode, the controller 1450 may be configured to cause detection of an enhanced WUS (compare with step 750 of FIG. 7).

To this end, the controller 1450 may comprise, or be otherwise associated with (e.g., connectable, or connected, to), a detector (DET2; e.g., detecting circuitry or a detection module) 1455. The detector 1455 may be configured to detect the enhanced WUS. In some embodiments, the detector 1455 is comprised in the WUR 1420 and/or the detector 1452.

The controller 1450 may be configured to cause enhanced WUS monitoring (compare with step 740 of FIG. 7) to enable detection of the enhanced WUS.

To this end, the controller 1450 may comprise, or be otherwise associated with (e.g., connectable, or connected, to), a monitor (MON2; e.g., monitoring circuitry or a monitor module) 1454. The monitor 1454 may be configured to monitor enhanced WUS occasion(s) where the enhanced WUS is expected.

Responsive to detection of an enhanced WUS, the controller 1450 may be configured to cause triggering of the communication device 1400 to leave sleep mode (compare with step 760 of FIG. 7).

To this end, the controller 1450 may comprise, or be otherwise associated with (e.g., connectable, or connected, to), a triggerer (TRIG; e.g., triggering circuitry or a trigger module) 1456. The triggerer 1456 may be configured to trigger the communication device 1400 to leave sleep mode. For example, the triggerer 1456 may be configured to trigger wake-up of the default transceiver 1430.

In some embodiments, the controller 1450 is configured to cause transmission of a DSM signaling capacity report (compare with step 305 of FIG. 3) and/or an enhanced WUS capacity report (compare with step 710 of FIG. 7).

In some embodiments, the controller 1450 is configured to cause reception of a DSM response scheduling message (compare with step 310 of FIG. 3).

Other features and examples relating to the operation of the apparatus 1440 and/or the communication device 1400 are derivable from the description in connection to FIGS. 3, 7, 10, and 11.

FIG. 15 schematically illustrates an example apparatus 1540 for monitoring and/or controlling a communication device in sleep mode.

For example, the apparatus 1540 may be comprisable (e.g., comprised) in a radio access node 1500 (e.g., a base station—compare with 101 of FIG. 1) or a relay node (e.g., a UE or a relay station-compare with 112, 103 of FIG. 1). Alternatively or additionally, the apparatus 1540 may be configured to cause execution of (e.g., execute) one or more method steps as described in connection with FIG. 2 and/or FIG. 6.

In some embodiments, the apparatus 1540 comprises, or is otherwise associated with (e.g., connectable, or connected, to), a transceiver (TRX; e.g., transceiving circuitry or a transceiver module) 1530. The transceiver 1530 may be any suitable transceiver for wireless communication. For example, transceiver 1530 may be comprised in the radio access node 1500, as illustrated by FIG. 15.

The apparatus 1540 comprises a controller (CNTR; e.g., controlling circuitry of a control module) 1550.

In some embodiments, the controller 1550 is configured to cause transmission of a DSM request to the communication device (compare with step 230 of FIG. 2). For example, the controller 1550 may be configured to cause the transceiver 1530 to transmit the DSM request.

Responsive to transmission of the DSM request, the controller 1550 may be configured to cause monitoring of reception of the DSM response (compare with step 235 of FIG. 2), wherein may comprise receiving the DSM response (compare with step 236 of FIG. 2) or noting absence of the DSM response (compare with step 237 of FIG. 2).

To this end, the controller 1550 may comprise, or be otherwise associated with (e.g., connectable, or connected, to), a monitor (MON; e.g., monitoring circuitry or a monitor module) 1551. The monitor 1551 may be configured to monitor for DSM response reception (e.g., within a period of time in which the DSM response is expected).

The controller 1550 may also be configured to cause registering of the communication device as reachable responsive to reception of the DSM response (compare with step 245 of FIG. 2), and registering of the communication device as unreachable responsive to noting absence of the DSM response (compare with step 255 of FIG. 2).

To this end, the controller 1550 may comprise, or be otherwise associated with (e.g., connectable, or connected, to), a registrar (REG; e.g., registering circuitry or a registration module) 1552. The registrar 1552 may be configured to register the communication device as reachable or unreachable.

The controller 1550 may also be configured to cause retransmission of the DSM request in response to noting absence of the DSM response, and continued monitoring of reception of the DSM response.

In some embodiments, the controller 1550 is configured to cause establishment of a restricted WUS activity mode of the communication device (compare with step 630 of FIG. 6).

To this end, the controller 1550 may comprise, or be otherwise associated with (e.g., connectable, or connected, to), an establisher (EST; e.g., establishing circuitry or an establishment module) 1553. The establisher 1553 may be configured to establish the restricted WUS activity mode.

Establishment of the restricted WUS activity mode may comprise reception of a do-not-disturb indication from the communication device (compare with step 632 of FIG. 6) or transmission of a will-not-disturb indication to the communication device (compare with step 634 of FIG. 6). For example, the controller 1550 may be configured to cause the transceiver 1530 to receive a do-not disturb indication and/or transmit a will-not-disturb indication.

In some embodiments, the controller 1550 may be configured to refrain from causing DSM request transmission while the communication device is in restricted WUS activity mode.

While the communication device is in restricted WUS activity mode, the controller 1550 may be configured to cause transmission of an enhanced WUS to the communication device (compare with step 640 of FIG. 6), to trigger the communication device to leave sleep mode. As already elaborated on, the enhanced WUS may be configured for more robust detection than one or more other WUS types.

In some embodiments, the controller 1550 is configured to cause reception of a DSM signaling capacity report (compare with step 205 of FIG. 2) and/or an enhanced WUS capacity report (compare with step 610 of FIG. 6).

In some embodiments, the controller 1550 is configured to cause transmission of a DSM response scheduling message (compare with step 215 of FIG. 2).

In some embodiments, the controller 1550 is configured to cause interaction with a monitoring manager node. For example, such interaction may be accomplished via an interface (IF; e.g., interfacing circuitry or an interface module) 1520, through which communication with the monitoring manager node is possible. Other features and examples relating to the operation of the apparatus 1540 are derivable from the description in connection to FIGS. 2 and 6.

According to some embodiments, another example apparatus is provided for a monitoring manager node, wherein the monitoring manager node is configured to manage monitoring of one or more communication devices during communication device sleep mode.

For example, such an apparatus may be comprisable (e.g., comprised) in a server node (e.g., a central network node or a cloud server—compare with 130, 141, 142 of FIG. 1). Alternatively or additionally, the apparatus 1540 may be configured to cause execution of (e.g., execute) one or more method steps as described in connection with FIG. 4 and/or FIG. 5.

Such an apparatus comprises a controller (e.g., controlling circuitry of a control module), which may be configured to cause one or more of: reception of monitoring result information for communication devices, maintenance of monitoring statistics for communication, provision of a DSM signaling configuration related to the specific communication device, and provision of monitoring result information for the specific communication device.

Generally, it should be noted that any feature/advantage described herein in connection with one Figure may be equally applicable—when suitable—in connection with one or more other Figures described herein, even if not explicitly mentioned in connection thereto.

The described embodiments and their equivalents may be realized in software or hardware or a combination thereof. The embodiments may be performed by general purpose circuitry. Examples of general purpose circuitry include digital signal processors (DSP), central processing units (CPU), co-processor units, field programmable gate arrays (FPGA) and other programmable hardware. Alternatively or additionally, the embodiments may be performed by specialized circuitry, such as application specific integrated circuits (ASIC). The general purpose circuitry and/or the specialized circuitry may, for example, be associated with or comprised in an apparatus such as a wireless communication device or a network node.

Embodiments may appear within an electronic apparatus (such as a wireless communication device or a network node) comprising arrangements, circuitry, and/or logic according to any of the embodiments described herein. Alternatively or additionally, an electronic apparatus (such as a wireless communication device or a network node) may be configured to perform methods according to any of the embodiments described herein.

According to some embodiments, a computer program product comprises a non-transitory computer readable medium such as, for example, a universal serial bus (USB) memory, a plug-in card, an embedded drive, or a read only memory (ROM). FIG. 16 illustrates an example computer readable medium in the form of a compact disc (CD) ROM 1600. The computer readable medium has stored thereon a computer program comprising program instructions. The computer program is loadable into a data processor (PROC; e.g., a data processing unit) 1620, which may, for example, be comprised in a wireless communication device or a network node 1610. When loaded into the data processor, the computer program may be stored in a memory (MEM) 1630 associated with, or comprised in, the data processor. According to some embodiments, the computer program may, when loaded into, and run by, the data processor, cause execution of method steps according to, for example, any of the methods illustrated in FIGS. 2-7, or otherwise described herein.

Generally, all terms used herein are to be interpreted according to their ordinary meaning in the relevant technical field, unless a different meaning is clearly given and/or is implied from the context in which it is used.

Reference has been made herein to various embodiments. However, a person skilled in the art would recognize numerous variations to the described embodiments that would still fall within the scope of the claims.

For example, the method embodiments described herein discloses example methods through steps being performed in a certain order. However, it is recognized that these sequences of events may take place in another order without departing from the scope of the claims. Furthermore, some method steps may be performed in parallel even though they have been described as being performed in sequence. Thus, the steps of any methods disclosed herein do not have to be performed in the exact order disclosed, unless a step is explicitly described as following or preceding another step and/or where it is implicit that a step must follow or precede another step.

In the same manner, it should be noted that in the description of embodiments, the partition of functional blocks into particular units is by no means intended as limiting. Contrarily, these partitions are merely examples. Functional blocks described herein as one unit may be split into two or more units. Furthermore, functional blocks described herein as being implemented as two or more units may be merged into fewer (e.g. a single) unit.

Any feature of any of the embodiments disclosed herein may be applied to any other embodiment, wherever suitable. Likewise, any advantage of any of the embodiments may apply to any other embodiments, and vice versa.

Hence, it should be understood that the details of the described embodiments are merely examples brought forward for illustrative purposes, and that all variations that fall within the scope of the claims are intended to be embraced therein.

1. A transmitter for operation with restricted power consumption, wherein the transmitter comprises:
a signal generation oscillator configured to provide a signal for transmission;
a phase-locked loop, (PLL) configured to calibrate an oscillator frequency of the signal generation oscillator in relation to a reference frequency, by providing a first control signal to the signal generation oscillator; and
holding circuitry configured to maintain a digital representation of the first control signal provided by the PLL, for provision of a second control signal to the signal generation oscillator when the PLL is inactive.

2. The transmitter of claim 1, wherein the PLL has a feedback path from the signal generation oscillator.

3. The transmitter of claim 2, wherein the feedback path comprises a frequency divider configured to specify a ratio between the reference frequency and the oscillator frequency.

4. The transmitter of claim 2, wherein the PLL comprises:
an error detector configured to receive the reference frequency and a feedback signal provided by the feedback path, and to provide a corresponding phase difference indicator; and
a loop filter configured to provide the first control signal based on the phase difference indicator.

5. The transmitter of claim 4, wherein the PLL is an analog PLL and further comprises one or more controlled current sources configured to provide charging based on the phase difference indicator, and wherein the loop filter is configured to provide the first control signal responsive to the charging.

6. The transmitter of claim 1, further comprising a reference oscillator configured to provide the reference frequency.

7. The transmitter of claim 1, wherein the holding circuitry comprises a successive approximation register (SAR).

8. The transmitter of claim 1, further comprising a digital-to-analog converter (DAC) configured to provide the second control signal to the signal generation oscillator based on the digital representation of the first control signal maintained by the holding circuitry.

9. The transmitter of claim 1, further comprising comparing circuitry configured to provide an input to the holding circuitry based on a difference between the first control signal and the second control signal.

10. The transmitter of claim 1, further comprising switching circuitry configured to provide the first control signal to the signal generation oscillator when the PLL is active, and to provide the second control signal to the signal generation oscillator when the PLL is inactive.

11. The transmitter of claim 1, further comprising controlling circuitry configured to cause:
the PLL to be active during a calibration phase, wherein the first control signal is provided to the signal generation oscillator during the calibration phase;
the holding circuitry and the PLL to be active during a settling phase, wherein the settling phase follows the calibration phase, wherein the first control signal is provided to the signal generation oscillator during the settling phase, and wherein the digital representation of the first control signal is attained by the holding circuitry during the settling phase; and
the holding circuitry to be active and the PLL to be inactive during a maintenance phase, wherein the maintenance phase follows the settling phase, and wherein the second control signal is provided to the signal generation oscillator during the maintenance phase.

12. The transmitter of claim 1, wherein the signal generation oscillator is operatively connectable to an antenna (1090, via tapping circuitry.

13. The transmitter of claim 1, wherein the transmitter is configured to modulate the signal for transmission using on-off keying (OOK).

14. The transmitter of claim 13, wherein the transmitter is configured to operate the signal generation oscillator in an active mode for provision of an on-symbol of the OOK and in an inactive mode for provision of an off-symbol of the OOK.

15. The transmitter of claim 12,
wherein the transmitter is configured to modulate the signal for transmission using on-off keying (OOK); and
wherein the transmitter is configured to operate the tapping circuitry between a signal transfer mode for provision of an on-symbol of the OOK and a signal blocking mode for provision of an off-symbol of the OOK.

16. The transmitter of claim 1, wherein the second control signal is an approximation of the first control signal.

17. The transmitter of claim 1, wherein the transmitter is configured to modulate the signal for transmission using frequency shift keying (FSK).

18. The transmitter of claim 17, wherein the transmitter is configured to dynamically adjust—for each FSK symbol—the digital representation of the first control signal provided by the holding circuitry to provide the second control signal as having a value that corresponds to the frequency for the FSK symbol.

19. The transmitter of claim 17, wherein the signal generation oscillator comprises a varactor configured to provide a shift of the frequency provided by the signal generation oscillator, and wherein the transmitter is configured to dynamically adjust—for each FSK symbol—a bias voltage of the varactor to provide the shift of the frequency provided by the signal generation oscillator as corresponding to the frequency shift for the FSK symbol.

20. The transmitter of claim 1, wherein a default transceiver is comprised in a same communication device as the transmitter, wherein the default transceiver is configured for operation with power consumption which is higher than the restricted power consumption of the transmitter and configured to be inactive while the communication device is in sleep mode, and wherein the signal for transmission comprises a signal to be transmitted when the communication device is in sleep mode.

21. The transmitter of claim 20, wherein the signal to be transmitted when the communication device is in the sleep mode comprises one or more of:
a radio link monitoring (RLM) report;
a deep sleep monitoring (DSM) response;
a response to, or confirmation of, a message received by a wake-up receiver (WUR) comprised in the same communication device as the transmitter;
a device status report;
a configuration report; and
a do-not-disturb indication.

22. The transmitter of claim 1, wherein the signal for transmission comprises an amount of data which is smaller than a data amount threshold.

23. An integrated circuit comprising the transmitter of claim 1.

24. The integrated circuit of claim 23, further comprising a wake-up receiver (WUR).

25. An integrated circuit chip comprising the integrated circuit of claim 23.

26. A communication device comprising the transmitter of claim 1.

27. The communication device of claim 26, further comprising a default transceiver configured for operation with power consumption that is higher than the restricted power consumption of the transmitter.

28. The communication device of claim 26, wherein the transmitter is configured to be operative while the communication device is in sleep mode.

29. The communication device of claim 26, wherein the communication device is powered only by a non-changeable, or non-rechargeable, power source and/or unpredictable power supply.
